(19) United States
(12) Patent Application Publication
(10) Pub. No.: US 2017/0183776 A1
(43) Pub. Date: Jun. 29, 2017

(54) ELECTROSTATIC CONTROL OF METAL WETTING LAYERS DURING DEPOSITION

(71) Applicant: Kenneth Scott Alexander Butcher, Ontario (CA)

(72) Inventor: Kenneth Scott Alexander Butcher, Ontario (CA)

(21) Appl. No.: 15/117,014

(22) PCT Filed: Jan. 28, 2015
(86) PCT No.: PCT/AU2015/050026

§ 371 Date: Aug. 5, 2016

(30) Foreign Application Priority Data
Feb. 11, 2014 (AU) 2014900403
May 26, 2014 (AU) 2014901976

(51) Int. Cl. C23C 16/50; C23C 16/455; H01L 21/02; C23C 16/06

(52) U.S. Cl. CPC C23C 16/50; C23C 16/06; C23C 16/45525; H01L 21/0254; H01L 21/02603; H01L 21/02653

(57) ABSTRACT

There is disclosed a system for the electrostatic control of a metal wetting layer during deposition and a method of electrostatically controlling a metal wetting layer during deposition using a deposition system. In one example, control of the metal wetting layer is provided by changing or applying an electrostatic field acting on a deposited material or acting on a substrate on which a material is deposited. In another example, control is of the thickness of the metal wetting layer. In another example, control is of the presence or absence of the metal wetting layer. The metal wetting layer can be a liquid metal or liquid metal alloy, for example the metal wetting layer could be Boron, Aluminium, Indium, Gallium or Thallium. In another example, control is of the thickness, or presence, of a Gallium wetting layer during GaN film growth.

### TECHNICAL FIELD

The present invention generally relates to film and nanostructure deposition using deposition systems and/or methods. More specifically, examples relate to the electrostatic control of metal wetting layers during deposition, such as when using plasma based systems and/or methods.

### BACKGROUND

The inventor has observed that when radio-frequency (RF) plasma generation is used for the remote plasma deposition of group III nitride semiconductors a powdery deposition was often produced, whereas when using a microwave generated plasma a continuous film was deposited. In some cases the powdery deposition was a true powder, due to gas phase reactions. However, in many instances it was found that the powdery deposition was not a true powder, but an instance of spontaneous nanowire deposition, as described in P. Terziyska, K. S. A. Butcher, D. Gogova, D. Alexandrov, P. Binsted and G. Wu, Materials Letters 106 (2013) 156 (Terziyska et al.).

In Terziyska et al. it is described that spontaneous nanowire deposition also occurs in pulsed deposition situations where gas phase reactions, and hence powder formation, are greatly reduced. This result is somewhat surprising, and not in agreement with some prior teachings. There are other situations where pulsed deposition has not resulted in the expected outcome. For example, it is taught that for the deposition of gallium nitride, gallium metal can be deposited as a metal bilayer before droplet formation occurs and that the presence of the metal bilayer greatly improves lateral crystal growth yielding better quality films (see E. J. Tarsa, B. Heying, H. Wu, P. Fini, S. P. DebBaars and J. S. Speck, J. Appl. Phys. 82 (1997) 5472 (Tarsa et al.), and B. Heying, R. Averbeck, L. F. Chen, E. Haus, H. Riechert and J. S. Speck, J. Appl. Phys. 88 (2000) 1855 (Heying et al.)).

This suggests that it should therefore be possible to deposit a monolayer of gallium metal, and subsequently nitride that layer as part of a continuous film, using migration enhanced epitaxy type (i.e. pulsed) techniques, however that is not always the case. This is demonstrated in FIG. 1, for static Molecular Beam Epitaxy (MBE) growth with a nitrogen plasma source, which is reproduced from Heying et al. The intermediate regime shown in FIG. 1 corresponds to Ga rich conditions where the Ga bilayer has been observed without the formation of gallium droplets. The intermediate regime is absent, or at least substantially absent, at temperatures below about 580° C. This indicates that the metal bilayer was not stable at such lower temperatures; that the gallium ‘wetting layer’ was absent, and that at such lower temperatures Ga droplet formation was dominant for the MBE system in which the results were produced.

A wetting layer is an initial layer of atoms that is grown on a sample, surface or substrate upon which films are created. The thickness and composition of the wetting layer, if present at all, can determine properties of the subsequently deposited film.

The inventor believes that the presence of a wetting layer, for example a Ga wetting layer as mentioned above, is very important for producing good quality films at reasonable growth rates and so that metal droplet formation is avoided (if this is actually desired for the results sought). Why a wetting layer exists in some deposition systems, but not others, does not appear to be presently understood.

The reference in this specification to any prior publication (or information derived from the prior publication), or to any matter which is known, is not, and should not be taken as an acknowledgment or admission or any form of suggestion that the prior publication (or information derived from the prior publication) or known matter forms part of the common general knowledge in the field of endeavour to which this specification relates.

### SUMMARY

This Summary is provided to introduce a selection of concepts in a simplified form that are further described below in the Preferred Embodiments. This Summary is not intended to identify key features or essential features of the claimed subject matter, nor is it intended to be used to limit the scope of the claimed subject matter.

In one aspect there is provided a deposition system for the electrostatic control of a metal wetting layer during deposition of a material. In an example form, there is provided a deposition system for the electrostatic control of a metal wetting layer during deposition of a material, comprising a device for producing an electrostatic field able to act on a deposited material or able to act on a substrate on which a material is deposited, wherein the electrostatic field can be changed or applied so as to control the metal wetting layer during deposition.

In another aspect there is provided a method of electrostatically controlling a metal wetting layer during deposition in a deposition system. In another example form, there is provided a method of electrostatically controlling a metal wetting layer during deposition in a deposition system, wherein the metal wetting layer is controlled by changing or applying an electrostatic field acting on a deposited material or acting on a substrate on which a material is deposited.

In one example form, the metal wetting layer is controlled by changing or applying an electrostatic field acting on a deposited material or acting on a substrate on which a material is deposited. In one example form, the thickness of the metal wetting layer is controlled. In one example form, a presence or an absence of the metal wetting layer is controlled. In one example form, the metal wetting layer is a liquid metal or liquid metal alloy. Preferably, the metal wetting layer is of boron (B), aluminium (Al), indium (In), gallium (Ga), thallium (Tl), or ununtrium (Uut).

In one example form, the thickness, or presence, of a gallium wetting layer during GaN film growth is controlled. In one example form, the formation of metal droplets during deposition is controlled. In one example form, the control of the formation of metal droplets is provided by changing or applying an electrostatic field acting on a deposited material or acting on a substrate on which a material is deposited. In one example form, the metal droplets are a liquid metal or liquid metal alloy. Preferably, the metal droplets are of boron (B), aluminium (Al), indium (In), gallium (Ga), thallium (Tl), or ununtrium (Uut). In one example form, the formation of metal droplets during nitride based nanowire growth is controlled. Optionally, the nanowire growth is under metal rich conditions.

In an example form, the system is a plasma based or assisted deposition system. In another example, the metal wetting layer is controlled by changing the electrostatic field between the plasma (of the plasma based or assisted deposition system) and a deposited material or between the plasma and a substrate on which a material (e.g. the metal layer) is deposited.

In one example form, the device for producing the electrostatic field is a grid or the like, and the metal wetting layer is controlled by electrically biasing or grounding the grid. In another example form, the grid is positioned above or near the substrate or sample. In another example, the grid is positioned between a plasma (or plasma source or plasma generating electrode if used) and the substrate or the sample at which deposition occurs.

Optionally, the grid is positively biased from about +20 V to about +200 V, thereby providing enhanced nanowire growth. Optionally, the grid is positively biased from about +50 V to about +80 V. Optionally, the grid is positively biased so that the grid is at or near the plasma potential when the system is a plasma based deposition system.

Optionally, the grid is negatively biased from between about −20 V to about −200 V, thereby suppressing metal droplet formation. In one example form, the grid is negatively biased from between about −20 V to about −200 V, thereby improving metalorganic utilisation.

In various example forms, the grid (i.e. the device for producing the electrostatic field) is a metallic grate, mesh or perforated component. More than one grid is used. Optionally, for example, the grid is positioned about 10 mm to about 100 mm away from the substrate or sample, or about 20 mm to about 50 mm away from the substrate or sample. Preferably, the grid is biased using a grid voltage source separate from a substrate holder voltage source.

In one example form, the system includes a hollow cathode and the grid is positioned between the hollow cathode and the substrate. Preferably, the grid is positioned closer to the substrate than to the hollow cathode.

In one example form, the system is one in which the substrate is coupled or strongly coupled to a plasma, and the control is achieved by electrically biasing the grid.

In one example form, the system is one in which the substrate is not coupled or strongly coupled to a plasma, and the control of the metal wetting layer is achieved by electrically biasing the substrate so that the substrate is more positive than the plasma.

In other example forms, the system includes a deflection grid positioned about, around, adjacent or near the substrate. The deflection grid can be grounded, can be positively biased or can be negatively biased to control aspects of metal droplet and/or metal wetting layer formation. The deflection grid can be used in combination with or separately to the grid.

### BRIEF DESCRIPTION OF FIGURES

Example embodiments are apparent from the following description, which is given by way of example only, of at least one preferred but non-limiting embodiment, described in connection with the accompanying figures.

FIG. 1 (prior art) illustrates a surface structure diagram defining Ga-flux conditions and substrate temperatures for Ga-droplet, intermediate, and N-stable growth regimes at a constant N flux (reproduced from B. Heying, R. Averbeck, L. F. Chen, E. Haus, H. Riechert and J. S. Speck, J. Appl. Phys. 88 (2000) 1855).

FIG. 2 illustrates an example plasma based or assisted system for deposition of a material.

FIG. 3 illustrates an example method for producing a thin film using a plasma based or assisted system.

FIG. 4 illustrates a representative diagram of pulses of a metalorganic species and active neutral species of nitrogen (“active nitrogen”).

FIG. 5 illustrates an example plasma based or assisted deposition system, i.e. a plasma processing reactor, and more specifically in this example a pulsed plasma system.

FIG. 6 illustrates more details of an example main chamber of a plasma processing reactor.

FIG. 7 illustrates a side view of an example deflection grid positioned about a substrate in a deposition system, where the deflection grid is grounded.

FIG. 8 illustrates a side view of an example deflection grid positioned about a substrate in a deposition system, where the deflection grid is electrically biased.

FIG. 9 illustrates carbon (C), hydrogen (H) and oxygen (O) concentration results for a GaN sample grown with a DC plasma potential of approximately +78 V presenting to a sample from a nitrogen plasma above the sample (with no grid in place).

FIG. 10 illustrates carbon (C), hydrogen (H) and oxygen (O) concentration results for a GaN sample grown with the grid biased to −50 V.

FIG. 11 illustrates plots of the absorption coefficient squared versus energy for the samples used in FIGS. 9 and 10.

### Preferred Embodiments

The following modes, given by way of example only, are described in order to provide a more precise understanding of the subject matter of a preferred embodiment or embodiments. In the figures, incorporated to illustrate features of an example embodiment, like reference numerals are used to identify like parts throughout the figures.

A wide variety of deposition systems, devices, reactors or apparatus, including for example various plasma based or assisted deposition systems, can be used or modified to implement embodiments of the present invention. In non-limiting examples, the deposition systems can include radio-frequency (RF) systems, microwave systems, pulsed systems, migration enhanced epitaxy systems, Molecular Beam Epitaxy (MBE) systems, Atomic Layer Deposition (ALD) systems, chemical vapour deposition (CVD) systems, plasma-enhanced chemical vapour deposition (PECVD) systems, or more generally systems using an inductively coupled source, a capacitively coupled source or a wave heated source. In a preferred embodiment, the system uses a pulsed plasma, such as migration enhanced epitaxy.

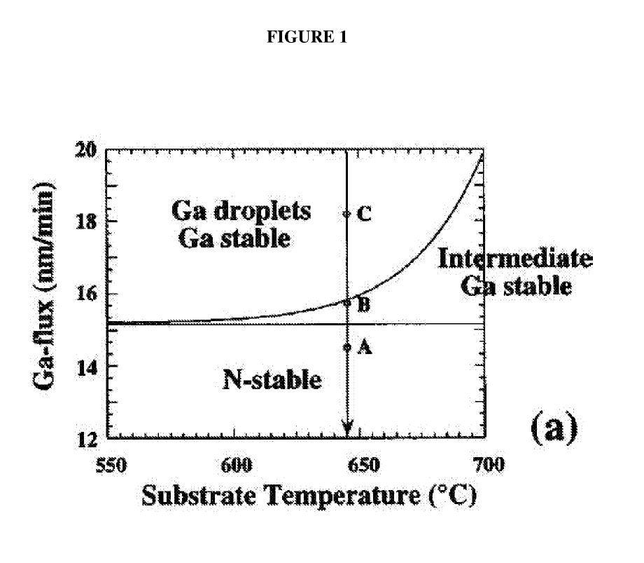

By way of example, using a migration enhanced epitaxy plasma system (a pulsed plasma system) at a plasma temperature of about 650° C., the inventor has found that it is possible to achieve one monolayer deposition per pulse cycle, indicating the presence of a metal (e.g. gallium) wetting layer. When growth occurred in the metal (e.g. gallium) droplet regime, referring to FIG. 1 by way of general characterisation, using the below described example system and method, metal rich nanowire growth was achieved (i.e. very rough layers).

In a preferred but non-limiting example, material deposition is for gallium nitride film growth. However, further examples include any other liquid metal or liquid metal alloy. Further examples also include the other group III nitrides and/or their alloys, being selected from the group of boron (B), aluminium (Al), indium (In), thallium (Tl), and ununtrium (Uut) nitrides, and/or nitrides of alloys thereof.

In still further examples, some of the beneficial effects apply to growth of other compound semiconductors, including rare earth nitrides, oxides, etc., wherever a liquid metal layer is used.

In a deposition system or apparatus, control of a metal wetting layer is provided by changing or applying an electrostatic field acting on a deposited material or acting on a substrate on which a material is deposited. An electrostatic field can be produced by a variety of devices. Preferably, an electric potential is applied to a grid (i.e. a grate, mesh, perforated component or the like) by a grid voltage source. The device for producing an electrostatic field, for example the grid, can be used to control aspects of the deposition of material(s) occurring on the substrate.

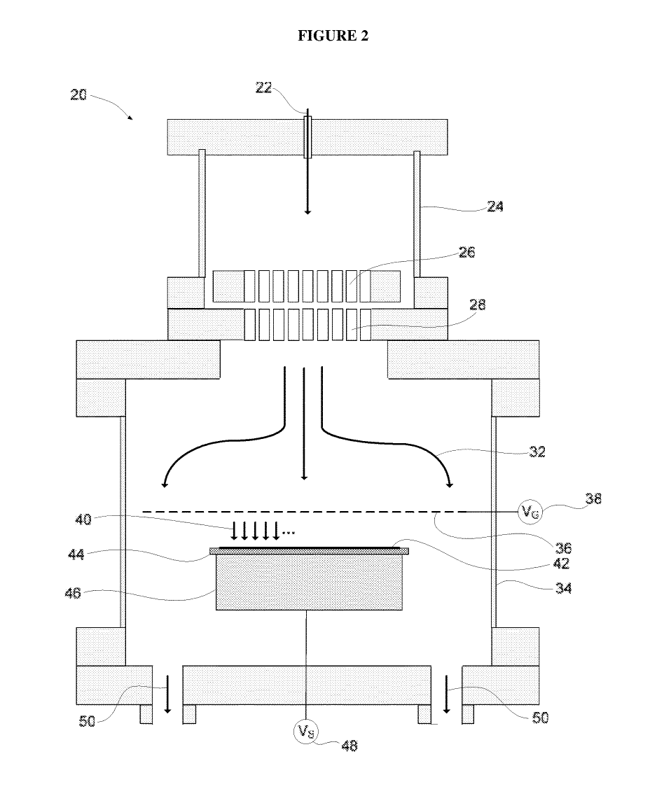

An example deposition system, in this non-limiting example case being a plasma based or assisted deposition system, i.e. plasma processing system, is illustrated in FIG. 2. Referring to FIG. 2 there is shown plasma processing system 20 which includes a plasma excitation source, which in this example is or includes a hollow cathode 26, for example a hollow cathode excited at RF frequency. Plasma processing system 20 receives gas 22 within housing or chamber 24, which can pass through hollow cathode 26 which acts to create plasma from gas 22. Optionally, an additional grounded hollow cathode/grid 28 can also be used, if desired, adjacent or near to hollow cathode 26. A grounded cathode/grid 28 can act as an electric potential shield to a certain extent, but the inventor has found that generally not enough active species of the gas 22 makes it to the substrate 42 using grounded cathode/grid 28, so the grounded cathode/grid 28 is preferably not used.

Plasma 32 is contained with housing or chamber 34 and moves towards grid 36 (i.e. a grate, mesh, perforated component or the like), which is preferably electrically biased, which creates a potential difference with respect to the plasma potential, either positive or negative, or neutral (i.e. equal), depending on requirements. Optionally, the grid 36 may be grounded instead. The electric potential is applied to grid 36 by grid voltage source (V_{G}) 38. The grid 36 can be used to control aspects of the interaction between plasma 32 and deposition of material(s) occurring on substrate 42, as grid 36, in this example, is positioned between hollow cathode 26 and substrate 42. In a preferred but optional application, a metalorganic species 40 is directed, for example using a nozzle such as a perforated inlet nozzle, towards substrate 42 which is held or supported by substrate holder 44. Substrate holder 44 can in turn be supported by or otherwise associated with a substrate holder pedestal 46 which may also include a heater. Optionally, an electric potential can be applied to substrate 42 by substrate voltage source (Vₛ) 48, or can act to ground substrate 42 and/or substrate holder 44. Gas/plasma flow 50 exits housing or chamber 34 to a vacuum system.

The plasma 32 can be brought closer to substrate 42 (by not using grounded cathode/grid 28), with grid 36 able to be used to effectively shield substrate 42 from the plasma. To provide an indication of some respective distances in a particular non-limiting example, grid 36 can be positioned about 4 cm above substrate 42, i.e. near the substrate (with substrate holder 44 grounded). The plasma was generated in hollow cathode 26 about 15 cm above the substrate 42, though with enough power, a high enough gas flow and low enough pressure, the plasma could extend to the grid 36. It should be appreciated that the grid need not necessarily be positioned wholly above the substrate or sample. The grid can be a variety of shapes, not necessarily planar, for example curved, annular, cylindrical, etc. The grid could be placed in any position near the substrate or sample where the grid produces the desired electrostatic field(s) acting on or in the vicinity of the substrate or the sample.

In one particular example, using a RF field the positive DC bias generated in this configuration (using 600 W of power and 1.1 Ton of nitrogen) was approximately +50 V to +100 V. So when +50 V was applied to grid 36, there was effectively no effect by grid 36, in terms of the influence on the substrate 42 (i.e. sample) from the plasma DC potential. When grid 36 was grounded the plasma potential was shielded from substrate 42. A negative bias of between about −20 V to about −200 V was applied for some experiments, though above about −50 V a DC plasma could occur between grid 36 and substrate holder 44. This DC plasma could cause some electron and negative ion bombardment of the substrate 42, which could be beneficial in some instances. For example, this scenario helps remove methyl groups from partially decomposed metalorganic, and also helps deliver the metalorganic to the sample holder more efficiently.

A radiofrequency (RF) generated plasma was used for the plasma processing system 20. Because of the higher mobility of electrons in a RF plasma compared to ions, the self-bias of the plasma is always more positive than any ground points in contact with (coupled to) the plasma. Therefore, there is an attractive force due to the direct current (DC) bias pulling electrons towards the plasma, while pushing positively charged ions away. When depositing a metal, such as gallium, on the surface of a grounded substrate, the metal has an electron cloud, and consequently the metal is pulled towards the positive bias presented by a plasma, thereby being less likely to wet the substrate surface and more likely to form a metal droplet.

Hence, there is a force acting to enhance growth outwards from a substrate and cause nanowire growth. For MBE systems the plasma does not couple to the substrate because of the lower pressures used, though some electric fields may still be evident. Therefore, in the lower electric fields of MBE systems, metal rich nanowire formation is likely to be less prevalent than in more strongly coupled RF plasma systems.

It should be noted that if the substrate is coupled to the plasma, in the sense of a relatively high gas pressure being used, then biasing the substrate (i.e. sample) (typically achieved by biasing the substrate holder) will have a small effect as the plasma should always drift to a more positive potential. As a plasma is a conductive medium, “coupling” of the plasma to the substrate/sample means the plasma extends to the substrate holder thereby providing a conductive path that affects the electric field at or about the substrate/sample. Below about 1 mTorr pressure it is very difficult to sustain a plasma, so below about 1 mTorr pressure the plasma would be decoupled from the substrate/sample. That is, in a particular example for this type of plasma deposition system, coupling of the plasma to the substrate/sample can occur for a pressure equal to or greater than about 1 mTorr.

However, in a system where the plasma is not coupled, or strongly coupled, to the substrate, such as MBE systems, it should be possible to control the bias of the substrate (via the substrate holder) so that the substrate is more positive than the plasma. This would suppress the formation of metal droplets, and allow greater wetting of the surface of the sample (i.e. an improved wetting layer). Hence, conditions of a gallium metal wetting layer, which in some cases may be a bilayer, could be achieved at lower temperatures (using the example plasma deposition system described and GaN, the lower temperature of about 480 ° C. was able to be achieved) for systems with the substrate appropriately biased.

In a plasma processing system where coupling of the plasma to the substrate can be relatively strong for some growth conditions, such as using a RF pulsed plasma processor, the inventor has found it to be advantageous to provide at least one electrically biased, or grounded, grid (i.e. a grate, mesh, perforated component or the like), between the substrate and the plasma, i.e. the plasma source or an electrode generating the plasma.

Positioning of the at least one grid is important. For example, a grounded grid positioned too close to the plasma (or plasma source) was ineffective in stopping the flow of ions downstream towards the substrate or sample. However, an electrically biased grid positioned closer to the substrate or sample (for example from about 10 mm to about 50 mm away, and in one specific example about 30 mm away) allowed the substrate or sample to be suitably shielded from the positive bias of the plasma. Depending on the outcome desired, the one or more grids used can be electrically biased positively or negatively, to create a potential difference (positive or negative or equal) relative to the plasma potential, or can be grounded, individually or collectively if more than one grid is used. A grid can be made, at least partially, of any electrically conducting material or materials, for example a metal. In a particular example, the grid is a stainless steel mesh with 1 mm diameter wire with a 5 mm throw.

Optionally, one or more grids can be used and different grids can have different electrical bias applied, for example a first grid can be positioned in one location and be electrically biased, positively or negatively, or grounded, and a second grid can be positioned in a second location and be electrically biased, positively or negatively, or grounded. Another level of control is to electrically bias, positively or negatively relative to the plasma potential, or ground, the substrate or sample, typically via the substrate or sample holder.
For example, depending on the application there can be provided:
at least one grid that is electrically biased, positively or negatively;
at least one grid that is electrically grounded;
two or more grids, with one or more of the grids electrically biased, positively or negatively; or
two or more grids, with at least one of the grids electrically biased, positively or negatively and at least one of the grids electrically grounded.

In one example, the system/method allows GaN to be grown at a monolayer per pulsed cycle rate or higher over a much broader range of conditions. Also, in examples using metalorganics, less metalorganic is needed to achieve the same growth conditions. This may be due, in part, to better metal coverage of the substrate (less droplet formation) when the substrate is isolated from the plasma's electric field. However, it may also be because a greater proportion of particular molecules, such as methyl groups in a particular example, were removed from the gallium during the decomposition of the metalorganic (trimethylgallium) used in this example. The final methyl group is fairly resistant to thermal decomposition so that some carbon usually remains in the film. At low temperatures insulating GaN is often grown and possibly the large amount of residual carbon (still bound to gallium) is responsible for this effect as carbon is often used as a dopant to create semi-insulating GaN.

Positively biasing the grid so that the grid is at or near the plasma potential, in present examples about +50 V to about +80 V, allowed nanowire growth with conditions similar to when no grid is present at all. Further biasing of the grid to higher positive potentials above +80 V, for example up to about +200 V, seemed to further enhance the effect of nanowire growth. This is also true for other examples such as indium nitride and indium gallium nitride nanowires.

Negatively biasing the grid, for example from about −20 V to about −200 V, suppressed both nanowire production and metal (e.g. Ga or In) droplet formation. Compared to a grounded grid, when using a negatively biased grid (for example about −50 V) even less metalorganic (in one example trimethylgallium) is needed to achieve the same growth conditions. Therefore, better metalorganic utilisation occurs when the grid is biased more negatively than the plasma potential.

The negative potential of the grid may also attract positively charged methyl groups, helping to further reduce carbon contamination in the film. Under these conditions there is slightly more oxygen uptake from negatively charged oxygen ions repelled from the grid to the substrate surface. Conducting films (with less carbon and more oxygen) can be achieved under these conditions since oxygen is an n-type dopant in gallium nitride.

Thus, in various example aspects the system and/or method provides for:

(1) Control of the thickness, or presence, of a metallic wetting layer.

(2) Control of the thickness, or presence, of a metallic wetting layer for group

III (boron (B), aluminium (Al), indium (In), gallium (Ga), thallium (Tl), and ununtrium (Uut)) nitride film growth. This wetting layer enhances the quality of group III nitride films when present during film growth.

(3) In a specific example, control of the thickness, or presence, of a gallium wetting layer during GaN film growth. This wetting layer enhances the quality of GaN films when present during film growth.

(4) Control of the formation of metallic droplets.

(5) Control of the formation of metallic droplets for group III (boron (B), aluminium (Al), indium (In), gallium (Ga), thallium (Tl), and ununtrium (Uut)) nitride based nanowire growth.

(6) In a specific example, control of gallium droplets for GaN nanowire growth. It should be noted that most GaN nanowires are grown under nitrogen rich conditions, whereas in contrast in the present system/method the GaN nanowires are grown under metal rich conditions.

(7) Use of a grounded or an electrically biased grid positioned between the plasma (or plasma source or plasma generating electrode) and the substrate or sample. A grid positioned between the plasma and the substrate or sample works better than simply biasing the substrate if there is any plasma coupling to the substrate.

(8) Removal or reduction of a species (e.g. carbon or oxygen) during film growth using a biased grid. That is, the grid is electrically biased resulting in removal or reduction of a species during deposition.

(9) Enhancement of a species (e.g. carbon or oxygen) during film growth using a biased grid. That is, the grid is electrically biased resulting in enhancement of a species during deposition.

(10) A means of carbon removal or reduction, for example when using a metalorganic, using a negatively biased grid positioned between the plasma and the substrate.

(11) A means of oxygen removal or reduction, using a negatively biased grid positioned between the plasma and the substrate.

(12) A means of growing conducting gallium nitride at lower temperatures.

Some example aspects or advantages of various embodiments include:

(1) Nanowire growth control.

(2) Wetting layer control and/or liquid metal (e.g. gallium) droplet formation control for improved film quality at relatively low growth temperatures.

(3) Thicker film growth per cycle for migration enhanced (pulsed growth) and possibly for some forms of Atomic Layer Deposition (ALD) growth. This can lead to higher growth rates.

(4) Carbon removal or enhancement (if an insulating layer is required).

(5) Oxygen removal or enhancement (if a conductive layer is required).

(6) Better metalorganic utilisation. For example, a plasma processing system used was able to improve from 0.8 sccm of TMG (trimethylgallium) with no grid to about 0.3 sccm of TMG with −50 V bias on the grid for approximately the same growth rate at about 650 ° C.

### Example Plasma Systems and Applications

The following examples provide a more detailed discussion of particular embodiments. The examples are intended to be merely illustrative and not limiting to the scope of the present invention. This section describes a non-limiting example plasma system that can be used to implement various embodiments of the invention.

In an example embodiment, plasma enhanced chemical vapor deposition (PECVD) and remote plasma enhanced chemical vapor deposition (RPECVD) based film growth systems are utilized (herein collectively referred to as plasma enhanced chemical vapor deposition, or PECVD), for example in the growth of compound semiconductors and insulators, and the gas phase delivery of the reactants is separated in time. This provides a significant reduction in the formation of dust particles for these plasma based film growth techniques. PECVD and RPECVD are generally used at relatively low temperatures compared to thermal growth techniques such as metalorganic chemical vapor deposition (MOCVD), and crystal quality can be problematic at such low growth temperatures.

Example embodiments advantageously reduce, if not eliminate, problems associated with dust formation and gas phase contamination during thin film formation.

In certain embodiments, a Group III metal precursor and active neutral species of N₂ are alternately and sequentially pulsed into a reaction chamber to form a Group III metal nitride film over a substrate. In an embodiment, each pulse of the Group III metal precursor forms a non-self limiting layer of a Group III metal, which can be subsequently contacted with active neutral species of N₂ to form a Group III metal nitride thin film.

“Metal nitride” can refer to a material comprising one or more metals or one or more semiconductors, and nitrogen. In certain embodiments, a metal nitride (e.g., metal nitride thin film) can have the formula MₓN_{y}, wherein ‘M’ designates a metal or a semiconductor, ‘N’ designates nitrogen, and ‘x’ and ‘y’ are numbers greater than zero. In some embodiments, a metal nitride can have the formula M_{z}N_{1-z}, wherein ‘z’ is a number greater than zero and less than 1. In some embodiments, ‘M’ can comprise one or more metals and/or semiconductors. In embodiments, MₓN_{y} refers to a metal nitride, such as a Group III metal nitride (e.g., gallium nitride, indium nitride, aluminum gallium nitride). In some embodiments, a metal nitride film or thin film can comprise other materials, such as, e.g., chemical dopants. Chemical dopants can include p-type dopants (e.g., Magnesium, Zinc) and n-type dopants (e.g., Silicon, oxygen).

“Plasma excited species” can refer to radicals, ions (cations, anions) and other excited species generated via application (or coupling) of energy to a reactant gas or vapor. Energy can be applied via a variety of methods, such as, e.g., induction, ultraviolet radiation, microwaves and capacitive coupling. The plasma generator may be a direct plasma generator (i.e., direct plasma generation) or a remote plasma generator (i.e., remote plasma generation). In the absence of coupling energy, plasma generation is terminated. Plasma-excited species include, without limitation, nitrogen radicals, nitrogen ions, and active neutral species of nitrogen. The source of plasma activated species may include, without limitation, N₂, NH₃, and/or hydrazine. For remote plasma generation, plasma-excited species of a particular vapor phase chemical (e.g., nitrogen containing plasma species) can be formed in a plasma generator in fluid communication with a reaction chamber having a substrate to be processed.

“Adsorption” can refer to chemical attachment of atoms or molecules on a surface.

“Substrate” can refer to any workpiece on which deposition, film or thin film formation is desired. Substrates can include, without limitation, silicon, silica, sapphire, zinc oxide, SiC, AlN, GaN, Spinel, coated silicon, silicon on oxide, silicon carbide on oxide, glass, and indium nitride.

“Surface” can refer to a boundary between the reaction space and a feature of the substrate.

“Cation species” can refer to a chemical, such as a vapor phase chemical, for depositing a metal or metal-containing species on or over a substrate. In embodiments, cation species can be used to deposit Group III metals on a substrate. A cation species can include one or more atoms of a Group III metal desired on a substrate. In an embodiment, cation species can include one or more Group III metals selected from boron (B), aluminum (Al), gallium (Ga) and indium (In). In various embodiments, the cation species is a Group III metal precursor (also “Group III metal-containing reactant” herein). In certain embodiments, the Group III metal precursor is a metalorganic species. In an embodiment, the Group III metal precursor can be trimethyl gallium or triethyl gallium. In embodiments, cation species are used to form a Group III metal nitride thin film, MₓN_{y}, wherein ‘M’ is a Group III metal, ‘N’ is nitrogen, and ‘x’ and ‘y’ are numbers greater than zero. The cation species can provide the Group III metal (M) for forming the metal nitride layer. In certain embodiments, ‘M’ can be a cation.

“Anion species” can refer to a chemical, such as a vapor or gas phase chemical, for providing nitrogen and/or oxygen to a metal on or over a substrate. In embodiments, anion species can be used to provide oxygen and/or nitrogen to a Group III metal on a substrate. In other embodiments, anion species can include mixtures of anions and noble gases, such as argon or neon, for providing oxygen and/or nitrogen to a Group III metal on a substrate. In embodiments, anion species can include active neutral species of nitrogen (N₂) (also “plasma-activated species of nitrogen” herein), which can be formed using a plasma generator.

Reference to supply of a cation species or an anion species can be read as also referring to supply of a cation species precursor or an anion species precursor. In an embodiment, cation species can include Group III metal precursors, such as, e.g., metalorganic species (also “organometallic species” and “metal organic species” herein). In an embodiment, anion species can include active neutral species of N₂.

Reference to modulating the supply of the cation species or the anion species to a substrate region can be read as encompassing any means of achieving such an effect. For example, modulating the supply of a species could be achieved by: a pressure of a species could be modified at or remote to the substrate region; a flow rate of injecting a species into a chamber could be modified; an evaporation rate of a species could be modified; a physical, electric or magnetic barrier could be used to modulate flux of a species between distinct areas; a pressure of a background gas, if present, could be modified; a plasma excitation source could be modified such as pulsed on or off; combinations of the foregoing; and/or various other mechanisms.

Reference to intermittently modulating the supply of the species can be read as any form of intermittent, periodic, interspersed, pulsed, or the like, modulation of two or more species. In a preferred example, modulation of the supply of each species is out of phase so that a maximum rate of supply of a first species is intermittent to a maximum rate of supply of a second species. The period, frequency and amplitude for modulation of each species can be independently changed as desired.

### Thin Film Growth

In an aspect of the invention, methods for forming thin films are provided. Methods of embodiments of the invention can be used to form Group III metal nitride thin films or layers. Group III metal thin films of embodiments of the invention can include one or more of boron (B), aluminum (Al), gallium (Ga), indium (In) and Thallium (Tl). In an embodiment, Group III metal thin films can comprise gallium nitride. In another embodiment, Group III metal thin films can comprise InN. In another embodiment, Group III metal thin films can comprise AlN. In another embodiment, Group III metal thin films can comprise alloys of GaN, AlN, and/or InN, such as InGaN, AlGaN, and/or AlInGaN.

In embodiments, a method of thin film crystal growth using plasma enhanced chemical vapor deposition includes intermittently modulating the supply of a cation species and an anion species to a substrate region. In certain embodiments, modulating the supply of a cation species and an anion species comprises pulsing cation species and anion species to a substrate region.

In embodiments, a method of producing a thin film using plasma enhanced chemical vapor deposition is provided, comprising the steps of supplying a cation species to a substrate region when there is at most a relatively low flux of a plasma based anion species in the substrate region, and supplying the plasma based anion species to the substrate region when there is at most a relatively low flux of the cation species in the substrate region.

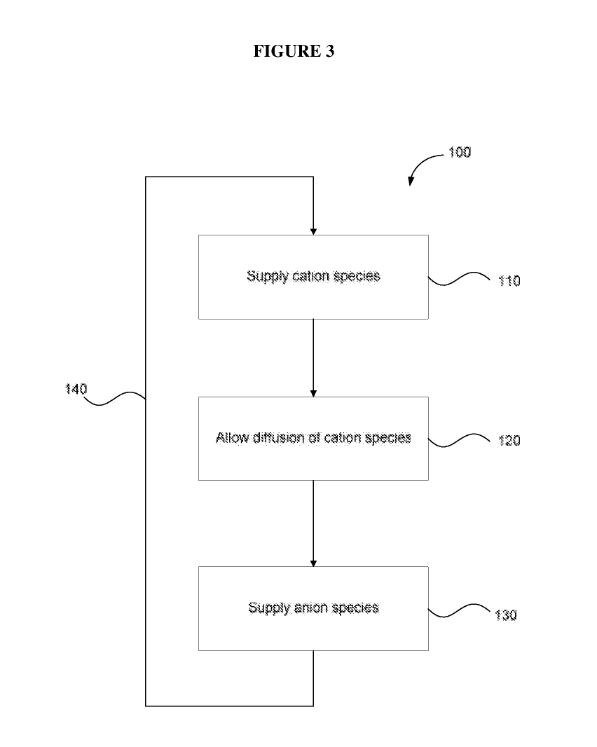

With reference to FIG. 3, there is illustrated a method 100 for producing a thin film using plasma enhanced chemical vapor deposition. At step 110, a cation species is supplied to a substrate (i.e., sample) region (for thin film growth on a substrate) with no, or a relatively low flux of a plasma based anion species being present. A relatively low flux can depend on specific chemistry of the species, but as an example could be between 0% and perhaps 50% of the normal or maximum flux of a species when supplied for film growth. At step 120, the cations are allowed sufficient time to diffuse on the film/substrate. This can be as part of the time duration when supplying the cations, or as a separate intermediate time delay step. In this way the cation is resident on a film surface long enough to be able to diffuse to an energetically favorable site for good film growth. This lateral growth can result in good quality thin film material at relatively low film growth temperatures. Then at step 130 the cation species flux is significantly reduced or stopped and a plasma based anion species is supplied to the substrate region. The process can be repeated at step 140, as required if necessary, to obtain a desired film thickness. The modulation of the supply of each species is preferably out of phase so that a maximum rate of supply of a first species is intermittent to a maximum rate of supply of a second species. The period, frequency and amplitude for modulation of each species can be independently changed as desired, for example a pulsed period of time for a species could vary significantly between about 1 second and 30 minutes. Thus, method 100 provides a means for migration enhanced epitaxy in a plasma enhanced chemical vapor deposition system.

This technique is ideally suited to the growth of some compound semiconductors, such as group III metal nitrides, rare earth nitrides, other nitride compound species and oxide compound species. With the introduction of migration enhanced epitaxy it is also possible to vary the growth conditions for a cation species (e.g., Group III metals including Boron, Aluminum, Gallium, Indium, Thallium) and an anion species (e.g., Nitrogen, Oxygen) separately, which can lead to some gains in improved precursor delivery. Obviously, a wide variety of other reactant species can be used.

In a specific but non-limiting example, the method of achieving migration enhanced epitaxy can be applied to known RPECVD based film growth of group III nitride films, for example the systems described in International Patent Publications WO2006/034540 and WO2003/097532, of which the present inventor is a co-inventor, which are entirely incorporated herein by reference.

An acronym that describes this technique is ME-RPECVD, or migration enhanced RPECVD. However, RPECVD reactors can also be referred to as afterglow reactors, so that the acronym MEAglow (migration enhanced afterglow), can be used. It should be noted that the technique can also be applied to PECVD systems.

In a specific illustrative example, known RPECVD based film growth methods can be generally used for the growth of good quality gallium nitride films at growth rates of less than 150 nanometers (“nm”)/hour. The achievement of higher growth rates is desirable to lower device deposition time, and to thereby allow RPECVD to be more competitive with MOCVD where growth rates as high as 2-3 micrometers (“m”)/hr can be achieved for good quality film growth.

However, achieving higher growth rates for the RPECVD growth of gallium nitride, for instance, is dependent on having a plasma source that produces a higher number of active nitrogen based species in the gas phase. Hence, a more efficient plasma source, capable of increasing the film growth rate, will incur the problem of a higher rate of dust formation. The low temperature growth by RPECVD of good crystalline quality GaN, has also been found to be less consistent than would be desirable. By using a MEAglow system capable of applying the aforementioned method, both these problems can be addressed.

In a particular illustrative example, a relatively short pulse of the gallium precursor material, trimethylgallium, is delivered at a much higher delivery rate than for normal RPECVD, which would cause the formation of excess gallium on the sample surface. The pulse is of sufficient duration to allow diffusion of the gallium species at the sample surface. A pulse of a remote nitrogen or ammonia plasma can then follow the pulse of metalorganic, to supply the nitrogen species used by RPECVD for film growth. In this way the reactant species are in the gas phase at separate times and dust formation is reduced, while the utilization of higher source flow fluxes allows faster growth rates to be achieved. In a MEAglow reactor higher film crystallinity than is observed for RPECVD can be achieved as a result of the diffusion of the group III metal component on the substrate surface prior to the delivery of the active nitrogen species.

Thus, the MEAglow reactor can be used to reduce the formation of dust during thin film growth by relatively high pressure film growth techniques, for example, operating approximately over a range of 0.1 mTorr to 10 Torr, compared to molecular beam epitaxy (MBE) which operates over a range of 0.000001 mTorr to 0.1 mTorr.

In various forms, modulating the supply of the anion species can be by changing a chamber pressure of the plasma. The chamber pressure could be adjusted to optimize a flux of the anion species to the substrate region and/or substrate while the plasma is on. Furthermore, the plasma can operate in continuous or pulsed modes. The chamber pressure may be adjusted to optimize the flux of the cation species to the substrate or substrate region, and to potentially eliminate the need for a carrier gas, so that cation species delivery could be by vapor phase delivery alone.

It should be appreciated that modulating the supply of the cation species or the anion species to the substrate region, which includes the actual substrate, can be achieved by a change in the chamber pressure between the use of the anion species and the cation species, or their respective precursors.

The pressure of the chamber of the cation species, or cation species precursor, can be relatively low to allow for delivery of the metalorganic without a carrier gas, i.e., the metalorganic can be supplied or delivered by vapor phase delivery alone when the chamber pressure is less than the vapor pressure of the cation species or cation species precursor. For supply or delivery of the anion species, the pressure, in a particular region such as for example a chamber housing an electrical source, can be optimized for efficient operation of a hollow cathode source, which operates in a narrow pressure range dependent on the dimensions of the hollow cathode and the power applied.

In embodiments, a method for producing a Group III metal nitride thin film comprises alternately and sequentially contacting a substrate in a reaction chamber with a Group III metal precursor and an active neutral species of nitrogen. In an embodiment, contacting the substrate with the Group III metal precursor forms a non-self limiting layer of a Group III metal over the substrate.

In an embodiment, the Group III metal precursor can include a vapor phase chemical comprising a Group III metal. In an embodiment, the Group III metal precursor comprises a metalorganic (or organometallic) species.

In an embodiment, the active neutral species of nitrogen comprises nitrogen species having energies less than or equal to 7 eV. In an embodiment, the active neutral species of nitrogen comprises N₂ species having the lowest excited state of molecular nitrogen (A³ᵤ⁺).

In embodiments, a method for forming a Group III metal nitride thin film over a substrate comprises contacting the substrate with a Group III metal precursor for a first time period to form a layer of a Group III metal having a thickness greater than 1 monolayer (ML). Next the layer of the Group III metal is contacted with plasma-activated species of nitrogen for a second time period to form a layer (or thin film) of a Group III metal nitride.

In embodiments, the first time period is greater than or equal to 10 seconds, or greater than or equal to 30 seconds, or greater than or equal to 1 minute, or greater than or equal to 10 minutes. In an embodiment, the layer or thin film of the Group III metal nitride has a thickness greater than 1 ML (monolayer), or greater than or equal to about 2 ML, or greater than or equal to about 5 ML. In an embodiment, the layer or thin film of the Group III metal nitride has a thickness greater than or equal the thickness of a quantum well.

In an embodiment, the plasma-activated species of nitrogen comprises nitrogen species having the lowest excited state of molecular nitrogen (A³ᵤ⁺).

In embodiments, a method for forming a metal nitride film over a substrate in a reaction chamber comprises alternately and sequentially pulsing into the reaction chamber a metal precursor and plasma-activated species of nitrogen, with each pulse of the metal precursor forming a non-self limiting layer of a metal over the substrate.

In embodiments, a method for forming a Group III metal nitride thin film over a substrate in a reaction chamber comprises alternately and sequentially pulsing into the reaction chamber a Group III metal precursor and plasma-activated species of nitrogen, with each pulse of the Group III metal precursor forming a non-self limiting layer of a

Group III metal over the substrate. In an embodiment, the plasma-activated species of nitrogen comprises nitrogen species having the lowest excited state of molecular nitrogen (A³ᵤ⁺). In an embodiment, the non-self limiting layer of the Group III metal has a thickness greater than 1 monolayer (ML). In another embodiment, the non-self limiting layer of the Group III metal has a thickness greater than 2 ML. In an embodiment, plasma- activated species of nitrogen having energies greater than 7 eV are quenched with, or prior to, each pulse of the plasma-activated species of nitrogen.

In other embodiments, a method for forming a Group III metal nitride thin film on a substrate comprises supplying a metalorganic species into a reaction chamber for a first time period to form a layer of a Group III metal having a thickness greater than 1 monolayer (ML). In an embodiment, the layer of the Group III metal is a non-self limiting layer of a Group III metal. Next, the metalorganic species is evacuated from the reaction chamber. In an embodiment, the metalorganic species is evacuated by directing N₂ into the reaction chamber. In another embodiment, evacuation can be achieved with the aid of a vacuum system alone or in combination with the use of N₂. Next, plasma-activated species of nitrogen are supplied into the reaction chamber for a second time period to form a layer of a Group III metal nitride. In an embodiment, the supply (or feed) of the metalorganic species is terminated before supplying the plasma-activated species of nitrogen into the reaction chamber.

In various embodiments, plasma-activated species of nitrogen are supplied to the reaction chamber by first forming the plasma-activated species of nitrogen with the aid of a plasma generator, and directing a subset of the plasma-activate species of nitrogen to the reaction chamber. In an embodiment, plasma-activated species of nitrogen are formed by supplying nitrogen (N₂) gas into the plasma generator. Next, the plasma-activated species of N₂ is generated in the plasma generator. In an embodiment, this is achieved by supplying power to the plasma generator. In an embodiment, plasma-activated species of nitrogen having potential energies greater than about 7 eV are quenched and plasma-activated species of nitrogen having potential energies less than or equal to about 7 eV are supplied in the reaction chamber. In an embodiment, the pressures in one or both of the plasma generator and an area downstream of the plasma generator (such as, e.g., the pressure in the reaction chamber) are selected such that plasma-activated species of nitrogen having potential energies greater than about 7 eV are quenched.

In various embodiments, the plasma generator comprises a gas distribution member for providing the plasma-activated species of N₂ to the reaction chamber. In an embodiment, the gas distribution member comprises a plurality of holes in a nozzle, tube, pipe, hollow member, or showerhead configuration. In another embodiment, the gas distribution member comprises one or more hollow cathodes. In an embodiment, the plasma generator comprises a hollow cathode configured to generate the plasma-activated species of nitrogen using an electrical source selected form the group consisting of a radiofrequency (RF) source, a lower frequency source, and a direct current (DC) source.

In an embodiment, the metalorganic species are supplied to the reaction chamber with the aid of a gas distribution member (such as a perforated nozzle, tube, pipe, hollow member, etc.) having a plurality of holes.

In embodiments, the layer of the Group III metal nitride has a thickness less than or equal to about 1 monolayer (“ML”), or greater than about 1 ML, or greater than or equal to about 2 ML, or greater than or equal to about 5 ML. In an embodiment, the layer of the Group III metal nitride has a thickness greater than or equal the thickness of a quantum well. Thus, the layer of the Group III metal nitride can have a thickness less than a monolayer, but greater than what can be achieved by ALD, which has chemically terminated layers.

In an embodiment, the plasma-activated species of nitrogen comprises active neutral nitrogen species having potential energies less then or equal to about 7 eV.

In embodiments, a method for forming a Group III metal nitride thin film over a substrate comprises (a) pulsing one of a Group III metal-containing reactant and plasma- activated species of nitrogen into a reaction chamber; (b) evacuating the reaction chamber; (c) pulsing the other of the Group III metal-containing reactant and plasma-activated species of nitrogen into the reaction chamber; and (d) repeating steps (a)-(c) until a Group III metal nitride thin film of predetermined thickness is formed. In an embodiment, each pulse of the Group III metal-containing reactant forms a non-self limiting layer of a Group III metal on or over the substrate. In various embodiments, each pulse of the Group III metal-containing reactant forms a layer of a Group III metal having a thickness greater than 1 monolayer (ML), or greater than or equal to about 2 ML, or greater than or equal to about 5 ML.

In certain embodiments, the reaction chamber can be evacuated between steps (c) and (d). This reduces, if not eliminates, the gas phase reaction between the Group III metal-containing reactant and plasma-activated species of nitrogen, which advantageously reduces, if not eliminates, dust formation. In an embodiment, after the pulse of the Group III metal-containing reactant, the reaction chamber can be evacuated prior to pulsing the plasma-activated species of nitrogen into the reaction chamber. In another embodiment, after the pulse of the plasma-activated species of nitrogen, the reaction chamber is evacuated prior to pulsing the Group III metal-containing reactant into the reaction chamber. In an embodiment, the reaction chamber can be evacuated with the aid of an inert gas, such as Ar, He, or N₂. In another embodiment, the reaction chamber can be evacuated with the aid of a vacuum pumping system, such as a turbomolecular (“turbo”) pump backed by a mechanical pump. In another embodiment, the reaction chamber can be evacuated with the aid of an inert gas and a vacuum pumping system.

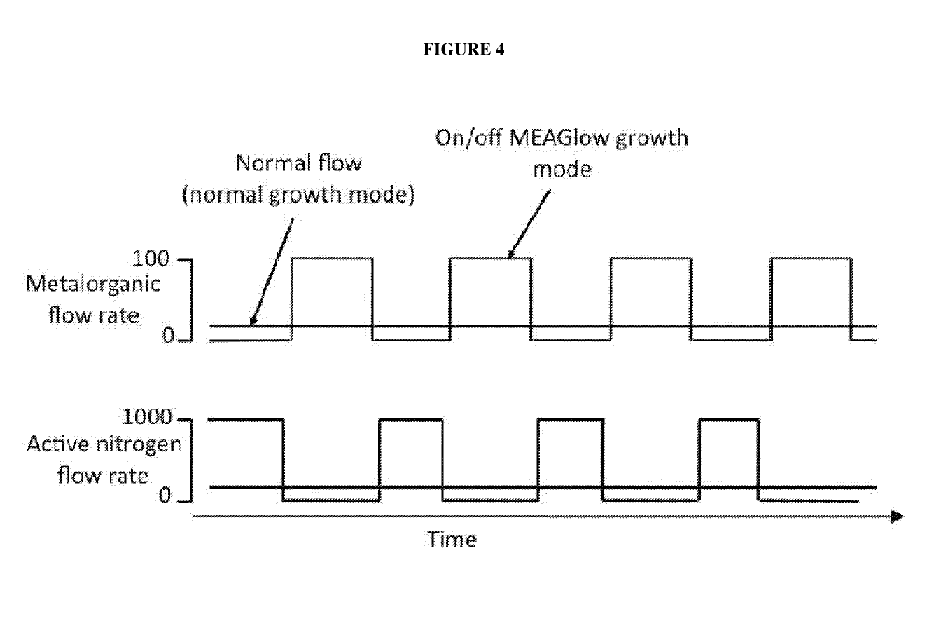

With reference to FIG. 4, a pulsing sequence (also “pulsing train” herein) for forming a Group III metal nitride thin film is illustrated. FIG. 4 shows an on/off pulsing sequence for a metalorganic species (top) and active neutral nitrogen species (bottom), with flow rates (arbitrary units) shown on the ordinates and time shown on the abscissa. In a preferable embodiment, a pulse of the metalorganic species does not overlap a pulse of the active neutral nitrogen (also “active nitrogen” herein) species. FIG. 4 also illustrates the growth mode during material pulses, designated as “On/off MEAglow growth mode”. The growth mode without material pulsing has also been illustrated (horizontal lines).

With continued reference to FIG. 4, in a first step, a pulse of a metalorganic species (or other vapor phase metal precursor) is provided into a reaction chamber (i.e., metalorganic species pulse turned ‘on’) having a substrate on which a Group III metal nitride thin film is to be formed. During the pulse of the metalorganic species, the flow rate of active nitrogen is terminated (i.e., active nitrogen is not directed into the reaction chamber). In an embodiment, this includes terminating the supply of N₂ gas into a plasma generator in fluid communication with the reaction chamber. The pulse of metalorganic species is provided for a time period and flow rate selected to form a Group III metal thin film of predetermined (or desired) thickness. Next, the flow of the metalorganic species into the reaction chamber is terminated. In a preferable embodiment, the Group III metal thin film formed in the first step is non-self limiting.

Next, the reaction chamber can be optionally evacuated with the aid of an inert gas and/or a vacuum pumping system (see above).

Next, following termination of the flow of the metalorganic species into the reaction chamber, in a second step, active neutral nitrogen is pulsed into the reaction chamber. During the second step, the substrate and metal thin film formed over the substrate are exposed to active nitrogen. In an embodiment, during the second step, at least a portion of the Group III metal thin film reacts with the active nitrogen to form a Group III metal nitride thin film.

Next, the reaction chamber can be evacuated with the aid of an inert gas and/or a vacuum pumping system (see above). In an embodiment, this can entail maintaining the flow of N₂ into the reaction chamber but not supplying power to the plasma generator, thus precluding the formation of active neutral nitrogen species.

Next, the first step and the second step, in addition to the evacuation steps, can be repeated until a Group III metal nitride layer or thin film of predetermined (or desired) thickness is formed over the substrate. Various process parameters, such as the duration of each of the metalorganic species and the active neutral nitrogen species pulses, chamber pressure, substrate temperatures and material fluxes, can be adjusted to achieve Group III metal nitride thin films with desired qualities and within a predetermined amount of time.

In various embodiments, with the pulse of a metalorganic species and the pulse of active nitrogen defining a cycle, a thin film can be formed following 2 or more cycles, or 5 or more cycles, or 10 or more cycles, or 20 or more cycles. It will be appreciated that a cycle can include one or more evacuation steps between the metalorganic species pulse and active nitrogen pulse.

In an embodiment, the duration of a metalorganic species pulse can be greater than or equal to about 1 second, or greater than or equal to about 3 seconds, or in the range of about 1 second to about 10 seconds, or greater than or equal to about 10 seconds, or greater than or equal to about 30 seconds, or greater than or equal to about 1 minute, or greater than or equal to about 10 minutes. In embodiments, the duration of an active nitrogen pulse can be greater than or equal to about 10 seconds, or greater than or equal to about 30 seconds, or greater than or equal to about 1 minute, or greater than or equal to about 10 minutes.

By alternately and sequentially pulsing into a reaction chamber a Group III metal precursor and active neutral nitrogen species, improved growth rates and thin film properties (quality, device performance) can be achieved. Pulsing methods and systems of embodiments of the invention can advantageously provide for improved growth rates.

### Plasma Processing Reactors

In a particular example embodiment, plasma processing reactors (also “plasma reactors” herein) are provided for deposition and/or forming thin films. In embodiments, plasma processing reactors comprise MEAglow reactors. In embodiments, the plasma processing reactors can be used to form Group III metal nitride thin films or layers, such as, e.g., gallium nitride thin films and indium nitride thin films.

In embodiments of the invention, plasma processing reactors can be used to form active neutral nitrogen species. In an embodiment, plasma processing reactors can be used to form active neutral nitrogen species having potential energies less than or equal to about 7 eV. In an embodiment, plasma processing reactors can be used to form active neutral nitrogen species having the lowest excited state of molecular nitrogen (A³ᵤ⁺). In a preferable embodiment, plasma processing reactors are used to form active neutral nitrogen species from molecular nitrogen (N₂).

In an embodiment, a method for forming active neutral nitrogen species, comprises supplying nitrogen (N₂) gas into a plasma generator. Next, plasma-activated species of N₂ are generated in the plasma generator. In an embodiment, plasma-activated species of N₂ includes nitrogen radicals, nitrogen cations and nitrogen anions. In another embodiment, plasma-activated species of N₂ includes active neutral species of nitrogen. In a preferable embodiment, plasma-activated species of N₂ having potential energies greater than about 7 eV are subsequently quenched. In embodiments, quenching of the higher energy species (e.g., high energy plasma-activated species of N₂ having energies greater than 7 eV) can be achieved by controlling the number of gas collisions that such high energy species undergo. In various embodiments, the pressure or pressures in one or both of the plasma generator and an area downstream of the plasma generator (such as, e.g., the pressure in a reaction chamber downstream of the plasma generator) are selected such that plasma-activated species of nitrogen having potential energies greater than about 7 eV are quenched. The distance in which quenching occurs (i.e., the distance high energy species travel before being quenched via collision with other gas phase species) is also dependent on the gas temperature and the flow rate of the gas, so that, in various embodiments, the gas temperature, the gas flow rate and/or the pressure will determine the distance that these species will travel before being quenched. In another embodiment, distance itself can be used to quench species with potential energy higher than 7 eV. In an embodiment, quenching can be achieved by selecting the distance between the plasma generator and the substrate in the reaction chamber. In another embodiment, the pressure in the plasma generator and/or downstream of the plasma generator selected to achieve such quenching (i.e., quenching plasma-activated species of nitrogen having potential energies greater than about 7 eV) is between about 0.1 mTorr and 10 Torr. Next, plasma-activated species of N₂ having potential energies less than or equal to about 7 eV, are then supplied to a reaction chamber (also “reactor chamber” and “chamber” herein) having a substrate. The substrate is then exposed to (or contacted with) such plasma-activated species of N₂.

In an embodiment, a method for providing active neutral nitrogen (N₂) to a reaction chamber comprises supplying nitrogen (N₂) gas into a plasma generator. Next, a first group of plasma-activated species of N₂ is formed in the plasma generator. A second group of plasma-activated species of N₂ is then formed from the first group, the second group comprising active neutral nitrogen species having potential energies less than or equal to about 7 eV. The second group is then directed to the reaction chamber having a substrate. In an embodiment, N₂ gas is supplied into the plasma generator at a pressure greater than or equal to about 0.1 mTorr. In another embodiment, N₂ gas is supplied into the plasma generator at a pressure greater than or equal to about 0.1 mTorr and less than or equal to 10 Torr.

In embodiments, a reactor for forming Group III metal nitride thin films or layers comprises a reaction chamber and a substrate holder disposed in the reaction chamber, the substrate holder configured to hold a substrate. The reactor further comprises a plasma generator in fluid communication with a nitrogen (N₂), ammonia (NH₃), and/or hydrazine feed and the reaction chamber, the plasma generator configured to form active neutral species of nitrogen. The reactor further comprises a control system (or computer system) configured to alternately and sequentially provide into the reaction chamber a Group III metal precursor and active neural species of nitrogen. In an embodiment, the control system is configured to rotate a substrate on the substrate holder while the substrate is alternately and sequentially exposed to a Group III metal precursor and active neutral species of nitrogen.

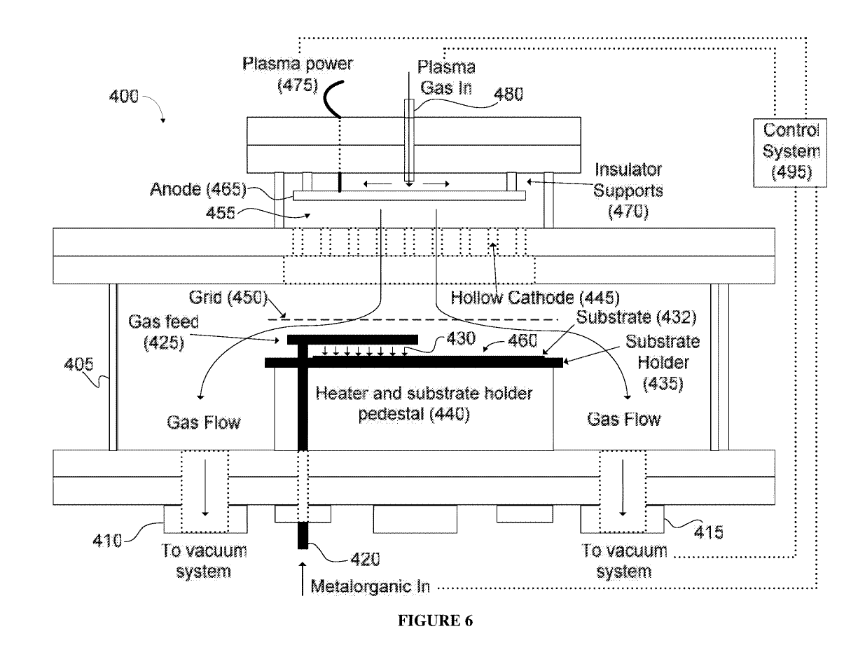

In an embodiment, the control system (such as control system 495 of FIG. 6) is configured to control various process parameters, such as, for example, substrate and/or substrate holder temperature, reactor pressure, reaction chamber pressure, plasma generator pressure, the flow rate of gas (e.g., N₂) into the plasma generator, the flow rate of gas (e.g., metalorganic species, active neutral species of nitrogen) into the reaction chamber, the rate at which the substrate rotates during thin film formation, power to the plasma generator (e.g., DC or RF generator), and a vacuum system in fluid communication with the reaction chamber. The vacuum system can comprise various pumps configured to provide vacuum to the reaction chamber, such as, e.g., one or more of a turbomolecular (“turbo”) pump, a cryopump, an ion pump and a diffusion, in addition to a backing pump, such as a mechanical pump.

In various embodiments, the plasma generator comprises a gas distribution member for providing active neutral species of nitrogen to the reaction chamber. In an embodiment, the gas distribution member comprises a plurality of holes in a showerhead configuration. In an embodiment, the gas distribution member comprises one or more hollow cathodes. In embodiments, the gas distribution member can be configured to form a group of active neutral species of nitrogen having potential energies less than or equal to about 7 eV. In a preferable embodiment, the plasma generator is configured to filter active neutral species of nitrogen having potential energies greater than about 7 eV to provide into the reaction chamber active neutral species of nitrogen having potential energies less than or equal to about 7 eV. In embodiments, during plasma formation, active nitrogen having the lowest excited state of molecular nitrogen (A³ᵤ⁺) is formed from a vapor or gas, or a plasma mixture of a vapor or gas, comprising various plasma excited species of nitrogen, thereby providing to a reaction chamber active nitrogen species having the lowest excited state of molecular nitrogen (A³ᵤ⁺). In various embodiments, the pressure in the plasma generator and/or the reaction chamber is selected such that high-energy active neutral species of N₂ (i.e., active neutral species of N₂ having potential energies higher than the lowest excited state of N₂), in addition to other plasma-excited species of nitrogen, are quenched via gas phase collisions. In an embodiment, the plasma generator pressure for providing active neutral species of nitrogen substantially having the lowest excited state of nitrogen (A³ᵤ⁺) is between about 0.1 mTorr and 10 Torr.

In embodiments, the reactor further comprises a Group III metal precursor feed for directing a Group III metal precursor to the reaction chamber. In an embodiment, the Group III metal precursor feed is disposed adjacent the substrate holder. In an embodiment, the Group III metal precursor feed is disposed between the substrate holder and the plasma generator. In some embodiment, the Group III metal precursor feed covers a portion of the substrate holder.

In other embodiments, the Group III metal precursor feed comprises a hollow head having a narrow end and a wide end, the narrow end configured to be positioned above a central portion of a substrate on the substrate holder, the wide end configured to be positioned above an outer portion of the substrate. In such a case, in an embodiment, a surface of the hollow head facing the substrate holder is provided with a plurality of holes configured to provide a Group III metal precursor to at least a portion of a substrate in the reaction chamber.

In various embodiment, upon supplying power to the plasma generator (e.g., RF generator), plasma excited species of nitrogen, such as active neutral species of nitrogen having various potential energies, nitrogen anions, nitrogen cations, and nitrogen radicals, are formed. Next, active neutral species of nitrogen having potential energies greater than about 7 eV are quenched, and active neutral species of nitrogen having potential energies less than or equal to about 7 eV are provided into the reaction chamber. In an embodiment, such species are quenched via collision with other gas phase species, the walls of the plasma generator, and/or the walls of the reaction chamber. In an embodiment, with the plasma generator pressure selected to be between about 0.1 mTorr and 10 Torr, active neutral species of nitrogen having potential energies greater than about 7 eV, in addition to other plasma excited species of nitrogen, are quenched, and active neutral species of nitrogen having potential energies less than or equal to about 7 eV are provided for distribution to the reaction chamber having the substrate. In an embodiment, the pressure in the plasma generator is adjusted via the flow rate of a nitrogen-containing species into the plasma generator. In an embodiment, the pressure in the reaction chamber can be the same or nearly the same as the pressure in the plasma generator, such that a change in reaction chamber pressure effects a change in the plasma generator pressure, and vice versa.

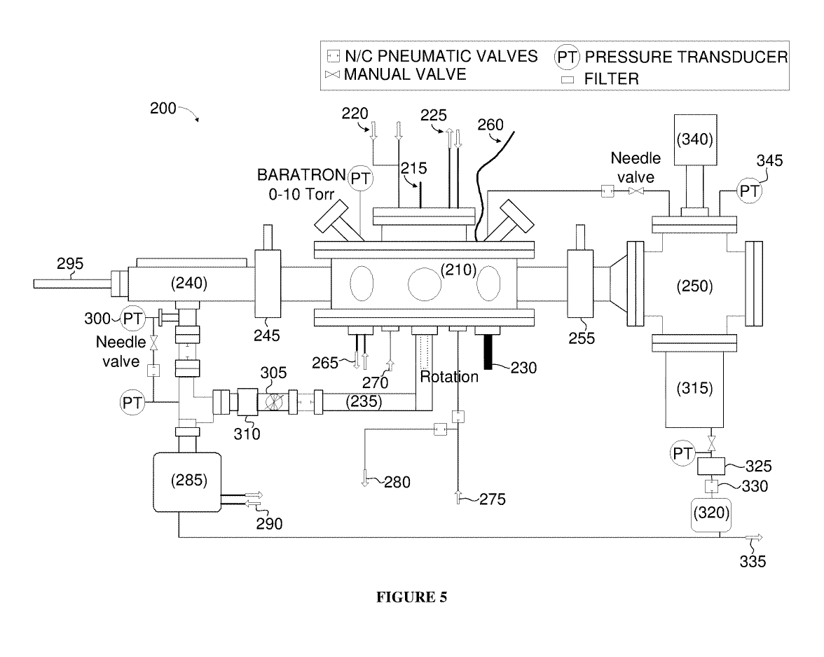

With reference to FIG. 5, there is illustrated a schematic of an example plasma processing reactor that provides a MEAglow reactor 200. Main chamber 210 is where reactions between chemical species occurs. A plasma power source 215 creates a contained plasma where plasma species are supplied by plasma supply lines 220. Plasma power source 215 can be cooled by water inlet/outlet 225. Main chamber 210 contains a substrate that can be adjusted in height by pneumatic sample lift 230. The region below the substrate can be connected to pump line 235 to assist in creating a vacuum in main chamber 210. Main chamber 210 is connected to load lock 240 via gate valve 245. Main chamber 210 is also connected to conflat cross 250 via gate valve 255.

An optical omission spectrometer optical fiber 260 can be introduced into main chamber 210 for diagnostic purposes. A further water inlet/outlet 265 and a purge valve 270 are associated with main chamber 210. A metaloraganic inlet 275 supplies a metalorganic species to main chamber 210. A bypass pump 280 is also connected to metalorganic inlet line 275.

Load lock 240 is connected to dry pump 285 with associated water inlet/outlet 290.

A transfer arm 295 is associated with load lock 240. Wide range gauge 300 can be used to measure the pressure on dry pump 285 side of load lock 240. Throttle valve 305 and filter 310 connect pump line 235 to dry pump 285.

Conflat cross 250 is connected to a turbo pump 315 which is connected to a backing pump 320 via filter 325 and electrical isolation valve 330. Backing pump 320 and dry pump 285 exhaust gas into exhaust line 335. RGA 340 is connected to conflat cross 250 which can also be provided with an associated wide range gauge 345.

With reference to FIG. 6, there is illustrated a schematic of an example main chamber of a plasma processing reactor providing part of a MEAglow reactor. Main chamber 400 includes housing 405 enabling a vacuum to be created in main chamber 400. Gas flow outlets 410 and 415 are connected to a vacuum system to remove gases from main chamber 400. Metalorganic species 430 is introduced internally into region 460 of main chamber 400 via metalorganic inlet 420, which is connected to gas feed 425. Gas feed 425 directs metalorganic species 430 onto or towards a substrate 432, which is held by or placed on substrate holder 435. Substrate holder 435 is supported by, and can be heated by, pedestal 440.

A hollow cathode 445 is provided above a grid 450 (or grate, mesh, component or the like) which can be electrically biased, positively or negatively relative to the plasma, or grounded. Gas flows through hollow cathode 445 from plasma creation region 455 into reaction region 460, being in the vicinity of the substrate 432 on substrate holder 435.

The hollow cathode 445 can generate a plasma using a variety of electrical sources, for example a radiofrequency (“RF”) source, a lower frequency source, a higher frequency source, and/or a DC source. This at least partially enables the plasma to be scalable to a relatively large area.

Anode 465 is supported by insulator supports 470 and attached to power line 475. A plasma based species is introduced into plasma creation region 455 via plasma gas inlet 480. A plasma can thus be created in region 455 that diffuses into region 460 to react with metalorganic species 430 on the substrate.

A capacitively coupled plasma can be formed between anode 465 and hollow cathode 445. This can be achieved by RF excitation of the anode 465 from RF power supply line 475. In this case, the plasma itself can act as a virtual anode, or by DC excitation of anode 465. There is some evidence to suggest that DC excitation results in higher density plasmas. In the holes in cathode 445, at certain gas flows and pressures, dependent on the geometry of the holes, a very strong additional plasma can be achieved due to the hollow cathode effect. Any additional plasma created by the hollow cathode effect can be, if desired, contained well above the substrate/sample by grid 450, since energetic ions can be damaging to the thin film during film growth.

Various advantages can be achieved using the MEAglow arrangement. For example, the growth rate of a material at the substrate can be increased compared to normal RPECVD growth. Also, plasma power sources other than microwave sources can be effectively applied. In particular, RF (Radio Frequency) and other lower frequency sources including DC can be used, particularly in the example case of a hollow cathode source.

For MEAglow, a hollow cathode source can be used under DC conditions and this can be advantageous in terms of obtaining an improved flux of active neutrals. In this particular but non-limiting example, because a microwave source is not used, relatively very large area deposition can be achieved.

In another example embodiment, oxygen contamination can be reduced by using a capacitively coupled parallel plate configuration, to eliminate the oxygen contamination that occurs when a plasma is in contact with dielectric windows. The parallel plate configuration can be used in conjunction with a hollow cathode plasma source to initiate a higher density plasma. A hollow cathode can be used, for example positioned between an anode and a cation species feed, where the hollow cathode and the anode provide a capacitively coupled configuration, and the plasma creation region is at least partially between the hollow cathode and the anode.

For example, there can be provided a plasma processing reactor, comprising a substrate holder positioned within a chamber for holding a substrate, a cation species feed to direct a supply of a cation precursor towards the substrate, the cation species feed positioned adjacent to the substrate. An anion species feed directs a supply of an anion precursor towards a plasma creation region in which a supply of a plasma based anion species can be created as at least part of a plasma. A hollow cathode can be positioned between an anode and the cation species feed, the hollow cathode and the anode providing a capacitively coupled configuration, and the plasma creation region is at least partially between the hollow cathode and the anode. Optionally, if desired, the supply of the cation precursor and the supply of the plasma based anion species to the substrate can be intermittently modulated.

Using such an arrangement contamination in film growth can be reduced by using a capacitively coupled configuration of the anode (e.g. anode 465) and the hollow cathode (e.g. hollow cathode 445) to eliminate contamination that would otherwise occur when a plasma is in contact with a dielectric window. The capacitively coupled configuration can be used in conjunction with the hollow cathode to initiate a higher density plasma. In various other plasma source systems, a dielectric window is used to transmit an electromagnetic field into a gas where the plasma is generated. It has been found that plasma interaction with the dielectric window can cause contamination of the plasma by species being etched or gases being ejected from the dielectric window, for example oxygen. By such use of the hollow cathode and the anode providing a capacitively coupled configuration, and where the plasma creation region is at least partially between the hollow cathode and the anode, a dielectric window is not required in this example embodiment and associated problems of dielectric windows are avoided. Thus, in these example embodiments, the capacitively coupled configuration of the hollow cathode and the anode can create the plasma without a dielectric window, and this can allow the capacitively coupled configuration of the hollow cathode and the anode to reduce or eliminate some species contamination, for example oxygen contamination, in the plasma creation region that would otherwise occur if the plasma was created using a dielectric window.

With continued reference to FIG. 6, the plasma processing reactor further comprises a control system 495 for controlling various process parameters and components, such as, for example, the substrate and/or substrate holder temperature, main chamber pressure, the flow rate of plasma gas (e.g., active neutral species of N₂), the flow rate of a metalorganic species, the rate at which the substrate rotates during thin film formation, power to the plasma generator (e.g., RF generator), and a vacuum system in fluid communication with the reaction chamber. The control system 495 can further control the pressure of the main chamber 400 and the pressure of the plasma creation region 455. In an embodiment, the control system is configured to alternately and sequentially provide non-overlapping pulses of a metalorganic species (or other Group III metal precursor) and active neutral species of nitrogen into the main chamber during thin film formation.

A gas feed 425 can be used in MEAglow reactor chamber 400. Gas feed 425 can be a variety of gas feed geometries, for example a shower head type or a perforated nozzle, tube, cylinder, pipe or other form of hollow member. Gas feed 425 distributes metalorganic species to the substrate/sample. The gas feed 425 can be located relatively close to the substrate/sample holder 435 as compared to a normal RPECVD system configuration. Holes are formed in a surface of the gas feed 425 to release metalorganic species. Holes direct metalorganic species 430 onto the substrate/sample. Optionally, substrate holder 435 is rotated about a longitudinal axis so that a substrate/sample rotates under gas feed 425 and so that metalorganic species is evenly distributed on the substrate/sample. Alternatively, gas feed 425 could move or rotate above a fixed, or moving, substrate holder 435.

According to other examples, a delivery head (of gas feed 425) can be of various configurations. The delivery head may be a series or an array of holes, for example forming part of a perforated nozzle. The delivery head may be substantially circular and cover the substrate, with exit holes provided about the circular extent of the head (i.e., a ‘showerhead’ configuration). This configuration might require the head to be moved (e.g., moved laterally) between pulses of metalorganic species. The delivery head may be of a ring-like or annular configuration with exit holes positioned about the ring-like or annular geometry. The delivery head may be of a form where the metalorganic species is introduced via a central hole or duct and is dispersed over the substrate by a dispersing mechanism, such as a rotating component creating a centrifugal dispersing action (e.g., a “turbodisc” configuration).

For the deposition of group III nitride semiconductor thin films by ordinary known RPECVD methods, the inventor has found that RF generated plasma supplies operating at 13.56 MHz have not proven particularly effective, with too much dust production being evident. In contrast, 2.45 GHz microwave plasma systems have proven to be more effective with substantially less dust production. It has been reported that for microwave generated plasmas less energy is required to sustain an electron-ion pair. For argon plasmas it has been estimated that 2-7 times less power per electron-ion pair is required at 2.45 GHz than at RF frequencies—dependent upon the discharge conditions. Hence, there is expected a greater degree of ionisation in a microwave generated plasma compared to an RF generated plasma for a given applied power. The excess energy used to generate an electron-ion pair for the RF case eventually devolves to heat, which would promote gas phase reactions and the formation of dust during ordinary RPECVD film growth. However, the electron density (and hence the degree of ionization—or electron-ion density) of an RF generated plasma is highly dependent on the means of generation. Capacitively coupled RF plasma generation (commonly used for semiconductor processing) is the least effective means, with electron-ion densities typically around 10⁹ to 10¹⁰ cm⁻³. While inductively coupled RF plasmas can typically have densities of 10¹¹ to 10¹² cm⁻³. This is similar to the densities achieved by microwave plasma systems, though typically less power is used in the case of the microwave source to achieve such densities. Other types of RF, or lower frequency plasmas, which utilize resonance characteristics, can be even denser. For instance, RF, and lower frequency, hollow cathode plasma sources, can produce high densities of ion-electron pairs.

For PECVD based processes, where substrates are in direct contact with the plasma, a high level of ionic species is usually a positive for plasma processes. This is also the case for RPECVD, and it is important to note that although the active species used in RPECVD film growth is not the ionic species, a greater degree of ionization within the plasma will generally translate into a denser (or more dense) concentration of neutral species in the afterglow region. Some RF based plasma systems may be suitable for RPECVD, if heating of the metalorganic reactants in the gas phase by the plasma source can be avoided.

In the case of RPECVD using a nitrogen gas source for the plasma, the lowest excited state of molecular nitrogen has an extremely long radiative lifetime, estimated to be as high as 2 seconds by some groups, and is a major contributing species to nitride film growth by RPECVD. For a hollow cathode source this lowest excited molecular nitrogen state has been observed to be present at densities as high as about 4.9×10¹¹ cm⁻³. In conventional RPECVD, however, it is known that collisions with some impurity species, including CH₄, is gas kinetic and will rapidly quench this form of neutral nitrogen at a rate of up to about 1000 times higher than collisions with molecular nitrogen.

For RPECVD film growth where excited nitrogen molecular neutrals and metalorganic species are present at the same time in the growth system, a notable reduction in the active nitrogen that reaches the substrate can be expected due to quenching caused by collisions with these methyl group species, resulting in a lower then expected growth rate. Gas phase reactions due to the interaction of the metalorganic with the active neutral nitrogen can also be expected. The inventor has observed a strong secondary light emission (chemiluminescence) in the far downstream afterglow of a microwave generated nitrogen plasma when metalorganic is introduced into the system, which suggests that such gas phase interactions are in progress. Using a migration enhanced configuration, where the metalorganic is not introduced at the same time as the active nitrogen should therefore allow a greater proportion of active species to reach the substrate to participate in film growth.

Microwave based plasma generation systems are electrodeless, a strong electromagnetic field in a resonant cavity leads to gas breakdown. A dielectric window is used to transmit the electromagnetic field into the gas system where the plasma is generated, usually at low pressure. It has been found that plasma interaction with the dielectric window can cause contamination of the plasma by species being etched from the window. A lengthy surface passivation cycle, taking as long as two days, in a well evacuated vacuum system that has no exposure to atmosphere is needed to create a nitride layer on the window to overcome this problem, as is outlined in International Patent Publication WO2006/034540, which is entirely incorporated herein by reference. Because of the relatively short wavelengths of microwave sources and the need to have dimensional cavities to sustain the plasma, it is also quite difficult to scale microwave sources for film deposition over large areas.

Although there are some advantages of the use of microwave plasma sources, the use of other sources, such as hollow cathode plasma sources, should allow for easier plasma source scalability and for reduced concern about contamination from windows. The use of a migration enhanced growth scenario would allow other plasma sources to be used without concern for gas heating which can result in enhanced dust formation problems. In particular, hollow cathode sources, which do not employ dielectric windows could be used.

Another advantage of a microwave plasma generation system is the ability to sustain the plasma over a very wide range of pressure. The inventor has been able to sustain a microwave generated nitrogen plasma over a 22 Torr to 10 mTorr range using a system capable of delivering approximately 600 W of power. Other RF and lower frequency (e.g., DC) generated plasmas do not generally have such a broad range of operating pressure. Again, using a migration enhanced methodology allows separate conditions to be used for the application of the metalorganic and the plasma, so that the chamber pressure for the delivery of the active nitrogen can be tailored to the plasma source used. To prevent high energy neutral species (such as atomic nitrogen) from reaching the substrate (which can happen at too low a growth pressure) the flow rate from the plasma source can be reduced and the distance from the plasma to the substrate can be adjusted, instead of adjusting the chamber pressure. This can provide a balance between having a high density of low energy active neutral species for film growth, while minimizing the presence of higher energy damaging species, which can affect film quality and reduce the growth rate through etching.

The delivery of the metalorganic for a migration enhanced film growth regime can be optimized to enable a higher delivery rate to the substrate. The gas head for the metalorganic can be positioned quite close to the substrate holder, and relatively low delivery pressures can be used to increase the utilization of the metalorganic. The requirement for uniform radial and axial delivery in the chamber, necessary during conventional RPECVD film growth, can be relaxed for film growth in a MEAglow reactor, with only radial uniformity being a necessary condition for design of the metalorganic delivery head.

During normal RPECVD film growth, rotation is used to “smooth out” small non-uniformities that occur axially, but because film growth is continuous during the process, uniform conditions are required to maintain uniform film properties that would otherwise be grown into the film. In contrast, for a MEAglow reactor, the film growth only occurs during the application of the plasma. Metalorganic delivery can therefore occur along a radius of the substrate holder so long as rotation of the substrate under that radius is rapid enough to provide uniform coverage of the substrate by the metal while the plasma source is off. The configuration of the metalorganic vapor delivery head can therefore be greatly simplified. Continued rotation while the plasma is on and the metalorganic is off ensures that any shadowing by the delivery head is not detrimental in terms of ensuring migration enhanced epitaxy occurs, and a uniform layer is deposited over the plasma on period.

For MEAglow, plasma sources other than RF or microwave plasma sources can be used because gas heating by the plasma source is less of an issue (powder production is reduced regardless). Because the conditions for delivery of a metalorganic cation and a plasma-generated anion are not congruent the conditions for the delivery of each precursor can be independently optimized. This also enables a simplified metalorganic delivery head to be used for MEAglow compared to RPECVD, or MOCVD. The chamber pressure during the delivery of the metalorganic cation can also be greatly reduced so that the use of a carrier gas with the metalorganic (as is typically used for RPECVD, MOCVD and PECVD) is not necessary. The metalorganic can be delivered as a pure vapor using a much simplified gas delivery system for which carrier mixing with the metalorganic is not required.

### Example Electrostatic Control Of Metal Wetting Layers During Deposition

### EXAMPLE CASE 1

### The MEAglow System was Initially Set Up with a Grounded Upper Grid Very Close to the Hollow Cathode Where the Plasma was Generated

With this configuration samples of GaN could be grown using pulsed delivery of gallium from the trimethylgallium (TMG) metalorganic source (0.35 to 1.2 sccm) while maintaining a constant source of nitrogen plasma (600W, 13.56 MHz RF). At the growth pressures typically used (1 to 2 Torr) the delivery of metalorganic effectively quenched the active nitrogen from the plasma, so that nitridation of gallium deposited on a substrate occurred mainly after the gallium had been deposited on the substrate. Using this method a monolayer or more of gallium could be put on the sample surface for a wide range of deposition temperatures (490° C. to 630° C.) and subsequently nitrided into an extremely smooth surface. An example of the surface of such a film had a root mean square (RMS) surface roughness 0.399 nm.

Films grown under these conditions were slightly metal rich, as indicated by transmission spectroscopy measurements. These measurements showed absorption below the about 3.4 eV band-gap of GaN due to defects introduced by excess metal in the film. The formation of a continuous film with terracing arising from the substrate used for the deposition of the equivalent of a monolayer of material per pulse, indicates the presence of a continuous metal wetting layer on the surface of the sample rather than the formation of metal droplets with no metal in between, as the latter case would result in very rough three dimensional growth.

A problem with these growth conditions is the excess metal in the film and the relatively long time per cycle (55 seconds being typical). Though the related growth rates were much higher than ALD (typical ALD growth rates for GaN are of the order of 2 nm/hour) they were still relatively low. Not enough active nitrogen was reaching the film. It should be noted however that the ALD of GaN is typically not a process that proceeds a monolayer at a time. Typically for ALD GaN takes 7-8 pulses to build a monolayer, it is very much a sub-monolayer growth process (which is true of many ALD growth processes) as opposed to the process described here.

Table I shows a selection of samples grown with 1 monolayer of GaN/cycle and with a grounded upper grid (not illustrated) in place near hollow cathode 445 of FIG. 6. Very smooth samples were achieved over a large temperature range though the optical transmission measurements for all of these samples showed evidence of below band-gap absorption that is typical of the presence of excess gallium in the film.

TABLE I

| Sample | Growth Temperature | RMS smoothness |
|---|---|---|
| 2011-06-13-1-GaN | 616° C. | 0.242 nm |
| 2011-07-06-2-GaN | 616° C. | 0.399 nm |
| 2011-07-13-1-GaN | 616° C. | 0.283 nm |
| 2011-09-05-1-GaN | 630° C. | 0.969 nm |
| 2011-09-14-1-GaN | 595° C. | 0.872 nm |
| 2011-09-27-1-GaN | 487° C. | 0.603 nm |
| 2011-10-03-1-GaN | 562° C. | 0.554 nm |
| 2011-12-03-1-GaN | 563° C. | 0.719 nm |
| 2011-12-08-1-GaN | 569° C. | 0.660 nm |

For the experiments in the above table pulse length was 55 second with the metalorganic being introduced for 30 of those seconds. The TMG flow was 1.0 sccm to 0.39sccm. The nitrogen gas flow for the plasma was 1400 sccm and the plasma power was at 600 Watts, the gas pressure in the chamber was 1200 mTorr.

### EXAMPLE CASE 2

### Removal of the Upper Grid Near the Plasma Source

The upper grid was then removed from the plasma source to provide more active nitrogen to the samples with the aim of improving growth rates and remedying the deficit of nitrogen in the films. However, using the same growth conditions much rougher samples were obtained as shown in Table II.

TABLE II

| | | |
|---|---|---|
| Sample | Growth Temperature | RMS smoothness |

| | | | |
|---|---|---|---|
| 2011-12-22-1-GaN | 579° C. | 28.8 | nm |
| 2011-12-22-2-GaN | 578° C. | 5.47 | nm |
| 2012-02-14-1-GaN | 568° C. | 10.9 | nm |
| 2012-02-14-2-GaN | 585° C. | 16.9 | nm |
| 2012-02-15-2-GaN | 577° C. | 15.2 | nm |

These samples actually showed evidence of surface nanostructures. Nanowire examples actually have metal droplets at an end (these could be etched away, whereas InN, InGaN and GaN are impervious to chemical etching).

Being able to grow nanowires under metal rich conditions is quite unusual. There appears to be a driving force for the migration of the metal atoms to the top of the nanowires. Given that metals have a highly conductive electron cloud, the Applicant believes they would be effected by a DC bias, such as that generated by an RF plasma. In fact, the positive potential generated by an RF plasma provides enough electromotive (electrostatic) force to provide a driving force that would allow migration of the metal species to the top of the nanowires.

In Table III below a wider range of results is given for Example Case 2. Here the deposition was not necessarily greater than a monolayer/cycle, but was near one monolayer per cycle, the metalorganic was between 0.3 and 1.6 sccm. Metalorganic delivery times of 4 to 30 seconds were used. Growth pressure was between 1200 to 2800 mTorr. Total cycle times of 10.5 to 55 seconds were used. This wider range of results show that smooth GaN surfaces could be obtained, though the parameter range was very narrow. Higher temperatures 620° C. and much lower amounts of TMG were required to obtain the smoother samples, though only one was in the same range as for Example Case 1, and for that sample (RMS roughness 0.952 nm) the growth was actually 0.21 nm/cycle which is less than one monolayer per cycle.

TABLE III

| | | |
|---|---|---|
| Sample | Growth Temperature | RMS smoothness |

| | | | |
|---|---|---|---|
| 2011-12-23-2-GaN | 578° C. | 18.1 | nm |
| 2011-12-27-1-GaN | 582° C. | 6.96 | nm |
| 2011-12-27-2-GaN | 578° C. | 4.75 | nm |
| 2011-12-27-3-GaN | 578° C. | 6.39 | nm |
| 2011-12-28-2-GaN | 566° C. | 9.04 | nm |
| 2011-12-28-3-GaN | 569° C. | 9.35 | nm |
| 2011-12-29-1-GaN | 569° C. | 13.9 | nm |
| 2011-12-29-2-GaN | 563° C. | 7.40 | nm |
| 2012-01-13-1-GaN | 570° C. | 5.70 | nm |
| 2012-01-13-2-GaN | 562° C. | 4.26 | nm |
| 2012-01-14-1-GaN | 562° C. | 7.07 | nm |
| 2012-01-16-1-GaN | 570° C. | 13.5 | nm |
| 2012-01-17-1-GaN | 570° C. | 10.9 | nm |
| 2012-01-18-1-GaN | 562° C. | 4.73 | nm |
| 2012-02-14-1-GaN | 568° C. | 10.9 | nm |
| 2012-02-14-2-GaN | 585° C. | 16.9 | nm |
| 2012-02-15-2-GaN | 577° C. | 15.2 | nm |
| 2012-03-14-1-GaN | 615° C. | 8.28 | nm |
| 2012-03-14-2-GaN | 615° C. | 24.5 | nm |
| 2012-03-14-3-GaN | 615° C. | 15.8 | nm |
| 2012-03-15-1-GaN | 615° C. | 20.5 | nm |
| 2012-03-15-2-GaN | 615° C. | 13.0 | nm |
| 2012-03-19-1-GaN | 618° C. | 16.1 | nm |
| 2012-03-19-2-GaN | 620° C. | 16.7 | nm |
| 2012-03-19-3-GaN | 625° C. | 7.24 | nm |
| 2012-03-20-1-GaN | 625° C. | 13.0 | nm |
| 2012-03-21-1-GaN | 616° C. | 12.2 | nm |
| 2012-03-21-2-GaN | 625° C. | 10.7 | nm |
| 2012-03-22-1-GaN | 658° C. | 11.7 | nm |
| 2012-03-22-2-GaN | 620° C. | 3.14 | nm |
| 2012-03-23-2-GaN | 630° C. | 1.14 | nm |
| 2012-03-24-1-GaN | 630° C. | 1.14 | nm |
| 2012-03-27-1-GaN | 630° C. | 4.00 | nm |
| 2012-03-27-2-GaN | 630° C. | 0.952 | nm |
| 2012-03-28-1-GaN | 633° C. | 7.69 | nm |
| 2012-04-24-1-GaN | 660° C. | 4.29 | nm |
| 2012-04-24-2-GaN | 660° C. | 5.50 | nm |
| 2012-11-16-1-GaN | 605° C. | 15.2 | nm |

The very much rougher films, that resulted from deposition rates near one monolayer/cycle, indicate that the wetting layer was absent for these films and that metal droplets were forming for metal deposition of less than one monolayer for many growth conditions. Nanostructures were then forming from the metal droplets. This was especially the case for lower temperatures less than 620° C. where no smooth layers could be achieved for deposition rates of near one monolayer/cycle.

It was possible in Example Case 2 to deposit smoother layers at low temperatures, but very low deposition per cycle values were needed, i.e. values well below a monolayer per cycle so that droplets were not forming. These values were well below the about 0.26 nm/cycle for a monolayer/cycle. Again this indicates that a full wetting layer was no longer present at low temperatures for Example Case 2.

TABLE IV

| | Growth Temperature | RMS Smoothness | nm/ |
|---|---|---|---|
| Sample | (° C.) | (nm) | cycle |
| 2012-04-10-2-GaN | 660 | 1.13 | 0.067 |
| 2012-04-16-1-GaN | 660 | 1.73 | 0.078 |
| 2012-04-16-2-GaN | 640 | 2.25 | 0.107 |
| 2012-04-26-1-GaN | 575 | 0.428 | 0.10 |
| 2012-05-01-1-c- | 520 | 0.445 | 0.12 |
| GaN | | | |
| 2012-05-13-1-GaN | 470 | 0.374 | 0.073 |
| 2012-05-21-2-Gan | 600 | 1.66 | 0.146 |
| 2012-05-29-1-GaN | 655 | 0.679 | 0.047 |

The absence of a wetting layer was detrimental for obtaining high growth rates. The growth rates for the samples in Table IV were approaching the lower rates of ALE. Also, best quality of material is obtained when a wetting layer covers the entire surface during nitridation.

### EXAMPLE CASE 3

### Grid Positioned Above the Sample Holder

Now using a grid positioned at about 4 cm above the substrate/sample (see grid 450 of FIG. 6 as an illustrative example), it was found that positively biasing the grid to a potential near the self-bias of the RF plasma, provided results very close to Example Case 2. On the other hand, grounding the grid improved the smoothness of the films in that smooth layers could again be obtained for a monolayer or more of deposition per cycle, see results in Table V, as for Example Case 1, though in this case a greater amount of active nitrogen was present so that more stoichiometric material was obtained. The formation of nanostructures was suppressed for a large parameter space for the examples of GaN, InGaN and InN.

TABLE V

| | Growth Temperature | RMS Smoothness | nm/ |
|---|---|---|---|
| Sample | (° C.) | (nm) | cycle |
| 2013-01-22-1-GaN | 640 | 1.32 | 0.220 |
| 2013-01-24-1-GaN | 645 | 0.68 | 0.248 |
| 2013-04-29-1-GaN | 630 | 1.53 | 0.249 |
| 2013-04-30-1-GaN | 630 | 1.98 | 0.30 |

### EXAMPLE CASE 4

### Grid Positioned Above the Sample Holder and Grid Bias to −50 V

Next, keeping the grid positioned at about 4 cm above the substrate/sample and biasing the grid to −50 V, the obtained samples were not quite as smooth as for Example Case 3. RMS surface roughness with most of the samples grown being between 3 and 4 nm for growth directly on sapphire. The advantage of this condition was that the samples were conductive, whereas for Example Cases 1 to 3 the samples were not conductive. It should be appreciated that the grid can be positioned at a variety of distances/positions above or near the substrate/sample that, depending on specific geometry or size, creates a suitable electrostatic field at or near the substrate/sample. For example, the grid could be positioned above or near the substrate/sample at a distance of about 10 mm to about 100 mm, or at a distance of about 20 mm to about 50 mm, or at a distance of about 10, 20, 30, 40, 50, 60, 70, 80, 90 or 100 mm.

Carbon retention from the metalorganic is a problem at low growth temperatures, the presence of carbon results in insulating films. Using the negative bias on the grid, positively charged methyl groups were more easily removed, resulting in the films being conductive due to the normal background n-type conductivity of the material. The amount of trimethylgallium used was also roughly halved in comparison to Example Case 3. With the improved carbon removal the most stoichiometric material was obtained with band-gaps (measured from optical transmission) providing values closest to that expected for high temperature grown GaN.

By the use of templates, or using buffer layers grown using Example Case 3, smoother surfaces can be achieved for Example Case 4. One such layer grown on a p-GaN template matched the RMS roughness of the template (1.88 nm).

### Deflection Grid(s)

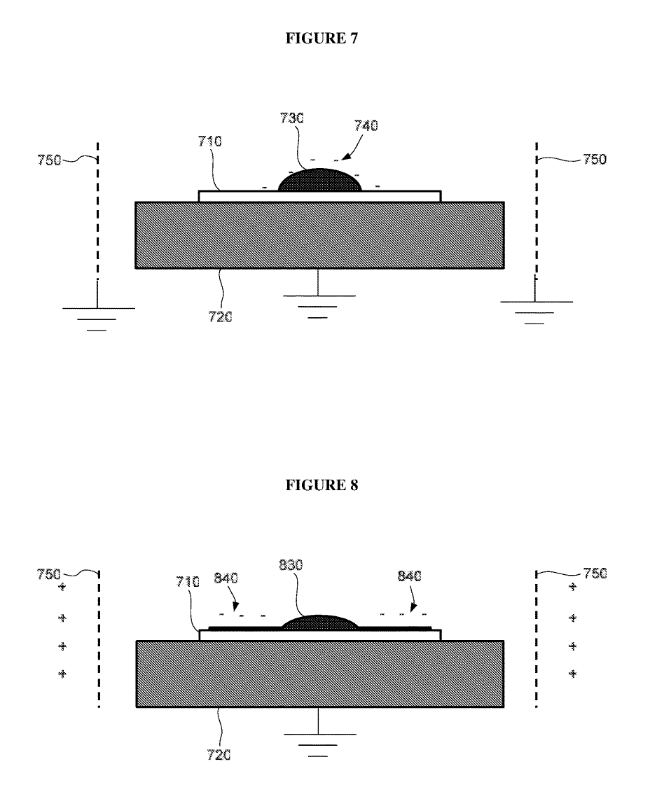

A further example embodiment is discussed with reference to FIGS. 7 and 8, which show part of a deposition system near the substrate. For example, the deposition system can be an MBE system. In a deposition system or apparatus, additional control of a metal wetting layer and/or a metal droplet can be provided by use of a deflection grid, which can be one or more deflection grids. The deflection grid (i.e. a grate, mesh, perforated component or the like) is grounded or a deflection grid voltage is applied from a voltage source. The deflection grid can be used to control aspects of the deposition of material(s) occurring on the substrate. The deflection grid can be used in combination with or separately to the previously discussed grid (e.g. grid 36). The deflection grid (or grids) can be provided in a variety of configurations, for example cylindrical, circular, planar, arcuate, etc. The deflection grid can be made from a variety of conductive materials, preferably being metallic.

FIGS. 7 and 8 show side views of illustrative examples for positioning of a deflection grid 750, which in this example is a cylindrically shaped deflection grid positioned about, around, adjacent or near a circular shaped substrate 710 supported on sample holder 720 (shown side-on). It should be noted that the relative size and spacing of components is for example illustration only, the figures are not to scale. Deflection grid 750 (or a plurality of deflection grids) can be used to divert ions (or attract ions) created by a plasma source from the surface of a film being deposited or grown so as to limit damage from high energy ion species.

In FIGS. 7 and 8, the effect on a metal droplet 730/830 (and/or wetting layer) when deposited on the substrate 710 is illustrated. Referring to FIG. 7, the metal droplet 730, having an electron cloud 740, is not affected when the deflection grid 750 is grounded. However, referring to FIG. 8, when the deflection grid 750 is positively biased, parts of the metal droplet 830, having an electron cloud 840, will be pulled outwards towards the deflection grid 750. In this situation, as the metal is consumed, for example by the formation of a nitride semiconductor film (as in the example of GaN), more metal from droplet 830 will be pulled out into the wetting layer by the biased deflection grid 750 to be further consumed. In other examples, the deflection grid 750 can be negatively biased.

Without biasing or electrostatic pull of any sort being applied by deflection grid 750 (as in the case of FIG. 7) the tops of the droplets 730 are nitrided but not completely, so only a very rough film is produced. In the example case of a strong positive bias from a plasma source, this would result in nanowires being formed.

With biasing or electrostatic pull applied by deflection grid 750, i.e. the deflection grid is used to apply an electric field in the vicinity or region of the substrate, (as in the case of FIG. 8) a smooth layer can be formed even when metal droplets 830 are present on the surface of the substrate 710, since the electric field is used to replenish the wetting layer from the droplet 830. The electric potential can be applied externally to metal droplets by the deflection grid, no direct connection is required.

### Example Results Showing Carbon Removal/Reduction

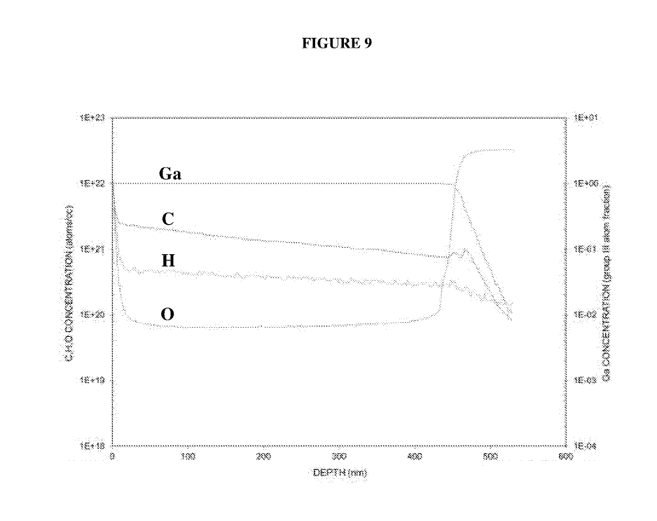

The following example results relate to demonstration of the removal or reduction of carbon. Referring to FIG. 9, there is presented carbon (C), hydrogen (H) and oxygen (O) concentration results for a GaN sample grown with a DC plasma potential of approximately +78 V presenting to the sample from the nitrogen plasma above the sample (with no grid in place). The associated SIMS for this sample shows carbon levels well above the oxygen level, and hydrogen levels above oxygen but not as high as carbon. The oxygen is due to post-growth exposure of this polycrystalline sample to air, and is present at grain boundaries. The SIMS results demonstrate that the carbon in this sample is a crystal impurity rather than from atmospheric exposure. It is known that the last methyl group for trimethylgallium is hard to remove. This sample was grown at about 680° C. (the sample holder temperature); hydrogen and ammonia were not used (these can help getter carbon, but the hydrogen from both is hard to remove). Carbon was a problem contaminant for this sample and caused the sample to be semi-insulating.

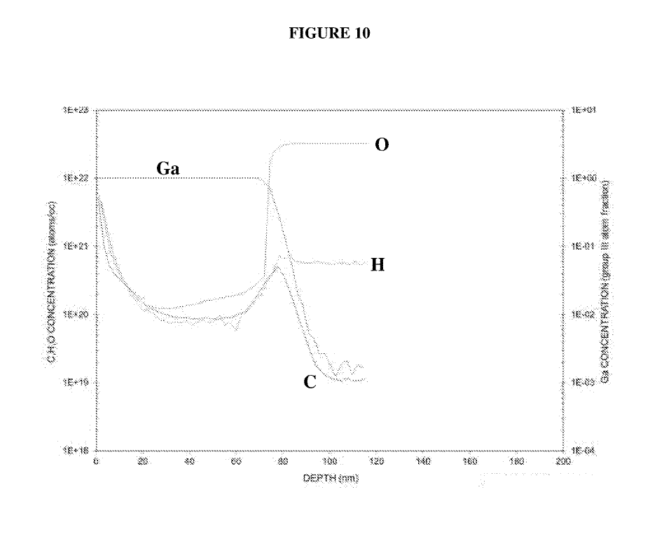

Referring to FIG. 10, there is presented carbon (C), hydrogen (H) and oxygen (O) concentration results for a GaN sample grown with the grid biased to −50 V. The SIMS shows lower carbon and hydrogen, in fact these elements are at the same level as the oxygen, which indicates that they are from atmospheric exposure down grain boundaries. The sample is also clear and conductive. The negative bias of the grid above the sample helped remove the residual methyl groups, which have a positive charge. Whereas the positive potential of the plasma, without a grid, repelled the methyl groups towards the sample surface.

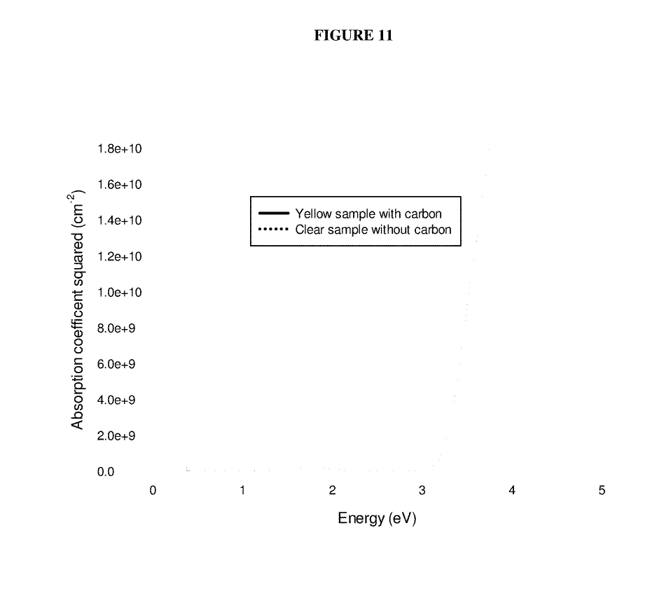

Referring to FIG. 11, there is shown a plot of the absorption coefficient squared versus energy, used to determine the band gap of direct band-gap semiconductors. The yellow sample (corresponding to FIG. 9) shows absorption well below the band-gap of GaN, which is band-tailing due to impurities with energy levels in the forbidden band gap of the GaN. For the clear sample with lower carbon (corresponding to FIG. 10) the −50 V biasing applied to the grid has clearly and considerably improved the GaN.

Optional embodiments of the present invention may also be said to broadly consist in the parts, elements and features referred to or indicated herein, individually or collectively, in any or all combinations of two or more of the parts, elements or features, and wherein specific integers are mentioned herein which have known equivalents in the art to which the invention relates, such known equivalents are deemed to be incorporated herein as if individually set forth.

Although a preferred embodiment has been described in detail, it should be understood that many modifications, changes, substitutions or alterations will be apparent to those skilled in the art without departing from the scope of the present invention.

1. A method of electrostatically controlling a metal wetting layer during deposition in a deposition system, wherein the metal wetting layer is controlled by changing or applying an electrostatic field acting on a deposited material or acting on a substrate on which a material is deposited.

2. The method of claim 1, wherein the metal wetting layer is controlled by electrically biasing or grounding a grid positioned above or near the substrate or a sample.

3. The method of claim 1, wherein the metal wetting layer is controlled by electrically biasing or grounding a grid positioned between a plasma source or a plasma generating electrode and the substrate or a sample.

4. The method of claim 1, wherein a thickness of the metal wetting layer is controlled.

5. The method of claim 1, wherein a presence or an absence of the metal wetting layer is controlled,

6. (canceled)

7. The method of claim 1, wherein the metal wetting layer is selected from the group of: boron (B), aluminium (Al), indium (In), gallium (Ga), thallium (Tl) and ununtrium (Uut).

8. The method of claim 1, wherein the thickness, or presence, of a gallium wetting layer during GaN film growth is controlled.

9. The method of claim 1, wherein formation of metal droplets during deposition of the material is controlled.

10. The method of claim 9, wherein the metal droplets are a liquid metal or a liquid metal alloy.

11. (canceled)

12. The method of claim 2, wherein the grid is electrically biased resulting in removal or reduction of a species during deposition.

13. The method of claim 2, wherein the grid is electrically biased resulting in enhancement of a species during deposition.

14. (canceled)

15. The method of claim 9, wherein the formation of metal droplets during nitride based nanowire growth is controlled.

16. (canceled)

17. A deposition system for the electrostatic control of a metal wetting layer during deposition of a material, comprising a device for producing an electrostatic field able to act on a deposited material or able to act on a substrate on which a material is deposited, wherein the electrostatic field can be changed or applied so as to control the metal wetting layer during deposition.

18. The system of claim 17, wherein the device comprises a grid positioned above or near the substrate or a sample, and the metal wetting layer is controlled by electrically biasing or grounding the grid.

19. The system of claim 17, wherein the device comprises a grid positioned between a plasma source or a plasma generating electrode and the substrate or a sample, and the metal wetting layer is controlled by electrically biasing or grounding the grid.

20. The system of claim 18, wherein the grid is positively biased from about +20 V to about +200 V.

21. (canceled)

22. The system of claim 18 or 19, wherein the deposition system is a plasma based deposition system, and the grid is positively biased at or near the plasma potential.

23. The system of claim 18, wherein the grid is negatively biased from between about −20 V to about −200 V.

24. (canceled)

25. (canceled)

26. (canceled)

27. The system of claim 18, wherein the grid is positioned about 10 mm to about 100 mm away from the substrate or the sample, or about 20 mm to about 50 mm away from the substrate or the sample.

28. (canceled)

29. The system of claim 18, including a hollow cathode, and wherein the grid is positioned between the hollow cathode and the substrate.

30. (canceled)

31. (canceled)

32. (canceled)

33. (canceled)

34. (canceled)

35. (canceled)

36. (canceled)

37. (canceled)
